(19) United States
(12) Patent Application Publication
(10) Pub. No.: US 2026/0110107 A1
(43) Pub. Date: Apr. 23, 2026

(54) SECURING CRYSTAL FEEDSTOCK FOR DEPLOYMENT IN ZERO GRAVITY GROWTH FURNACES TO MANUFACTURING SATELLITES

(71) Applicant: Jason KRIZAN, Ellicott City, MD (US)

(72) Inventor: Jason KRIZAN, Ellicott City, MD (US)

(21) Appl. No.: 19/168,484

(22) PCT Filed: Mar. 22, 2024
(86) PCT No.: PCT/US2024/021100

§ 371 Date: Sep. 24, 2025

Related U.S. Application Data
(60) Provisional application No. 63/454,614, filed on Mar. 24, 2023.

(51) Int. Cl. C30B 13/28; C30B 13/02; C30B 30/08

(52) U.S. Cl. CPC C30B 13/285; C30B 13/02; C30B 30/08

(57) ABSTRACT

A crystal growth furnace includes securing member(s) configured to retain a crystal growth feedstock within a crystallization zone. Securing member(s) can include movable retaining arms configured to releasably hold the feedstock in a secured configuration in which a distal portion of the movable retaining arms abut an outer surface of the feedstock, and transitioned to a released configuration in which the movable retaining arms are moved away from the outer surface of the feedstock. Securing member(s) can 2024/206123 be inflatable and configured when in a deflated configuration to allow the feedstock to be disposed within the crystallization zone, transitioned to an inflated configuration in which an outer surface of the inflatable securing member(s) abut an outer surface of the feedstock, and transitioned back to the deflated configuration such that the outer surface of the inflatable securing member(s) are moved from the outer surface of the feedstock.

### CROSS-REFERENCE TO RELATED APPLICATIONS

This application claims the benefit of priority to U.S. Provisional Application Ser. No. 63/454,614, filed Mar. 24, 2023 and entitled “Zero Gravity Crystal Growth Furnace,” the entire disclosure of which is hereby incorporated herein by reference in its entirety for all purposes.

### TECHNICAL FIELD

The present application relates to systems, devices, and methods for growing crystals, and more particularly to systems, devices, methods, and computer program products for crystal growth in reduced gravity environments.

### BACKGROUND

Crystals are often used in electronics, telecommunications systems, energy and information transfer, and otherwise. Crystals with minimal or no imperfections can provide many advantages in these and other applications over crystals with any/more imperfections. However, due to gravity-related convection during crystallization and other perturbations during terrestrial crystal growth, the probability of crystal imperfections significantly reduces performance of the crystals in their application, or reduces production yield due to the need to discard crystals that are imperfect or which include too many imperfections.

### BRIEF SUMMARY

Described are systems, devices, methods, and computer program products for growing crystals in a reduced gravity (e.g., zero-gravity) environment, such as in orbit about a planetary-mass object. The device (e.g., a crystal growth furnace) includes a crystallization zone configured to receive a volume of a crystal growth feedstock. The device includes securing member(s) configured to retain the volume of the crystal growth feedstock within the crystallization zone. The securing member(s) can include movable retaining arms configured to releasably hold the crystal growth feedstock within the crystallization zone in a secured configuration (e.g., before and during transportation of the crystal growth furnace into the reduced gravity environment) in which a distal portion of the movable retaining arms abut an outer surface of the volume of the crystal growth feedstock, and further configured to be transitioned to a released configuration in the reduced gravity environment and before crystal growth in the device in which the movable retaining arms are moved a non-zero distance away from the outer surface of the volume of the crystal growth feedstock. The securing member(s) can include inflatable securing member(s) configured in a deflated configuration to allow the volume of the crystal growth feedstock to be disposed within the crystallization zone, further configured to be transitioned to an inflated configuration in which an outer surface of the inflatable securing member(s) abut an outer surface of the volume of the crystal growth feedstock (e.g., before and during transportation of the crystal growth furnace into the reduced gravity environment), and further configured to be transitioned back to the deflated configuration before crystal growth in the device such that the outer surface of the inflatable securing member(s) are moved a non-zero distance from the outer surface of the volume of the crystal growth feedstock.

According to an embodiment, a crystal growth furnace can be provided that comprises a securing device. The securing device (device) can be configured for securing a crystal growth feedstock in the crystal growth furnace. The device can comprise a crystallization zone configured to retain a volume of crystal growth feedstock; and a plurality of movable securing members, respective movable securing members of the plurality of movable securing members comprising a distal portion configured to be disposed against an outside surface of the volume of the crystal growth feedstock when the plurality of movable securing members are in a first configuration and configured to be positioned a non-zero distance from the outside surface of the volume of the crystal growth feedstock when the plurality of movable securing members are in a second configuration.

According to another embodiment, a device can be provided that is configured to secure crystal growth feedstock in a crystal growth furnace, the device comprising: an expandible sample chamber comprising a flexible enclosure material, wherein when the expandible sample chamber is in a first configuration the expandible sample chamber is expanded to a maximum internal volume, and wherein when the expandible sample chamber is in a second configuration the expandible sample chamber is collapsed to a minimum internal volume; a crystallization zone configured to retain a volume of crystal growth feedstock; and a plurality of movable securing members, respective movable securing members of the plurality of movable securing members comprising a distal portion configured to be disposed against an outside surface of the volume of the crystal growth feedstock when the plurality of movable securing members are in a secured configuration and configured to be positioned a non-zero distance from the outside surface of the volume of the crystal growth feedstock when the plurality of movable securing members are in an extended configuration.

According to another embodiment, a device can be provided that is configured to secure crystal growth feedstock in a crystal growth furnace, the device comprising: a crystallization zone configured to retain a volume of crystal growth feedstock; and one or more inflatable securing members. In some embodiments, the one or more inflatable securing members are configured, when in a deflated configuration, such that an outer surface of the one or more inflatable securing members are maintained a non-zero distance from an outer surface of the volume of the crystal growth feedstock in the crystallization zone. In some embodiments, the one or more inflatable securing members are configured, when in an inflated configuration, to be inflated such that at least a portion of the outer surface of the one or more inflatable securing members abut at least a portion of the outer surface of the volume of the crystal growth feedstock.

According to another embodiment, a device can be provided that is configured to secure crystal growth feedstock in a crystal growth furnace, the device comprising: an expandible sample chamber comprising a flexible enclosure material and defining a collapsed volume within the flexible enclosure material; a plurality of feedstock retention points within the expandible sample chamber, the plurality of feedstock retention points defining a crystal growth region; one or more seed crystals disposed within the expandible sample chamber, at least one of the seed crystals being located at a feedstock retention point; a thermocouple configured to communicate heat to one or more portions of the crystal growth region within the expandable sample chamber; and a plurality of movable securing members configured to retain a volume of a solid or semi-solid feedstock within the crystal growth region of the expandible sample chamber.

In some embodiments, the expandible sample chamber is configured to be expanded from the collapsed volume to an expanded volume greater than the collapsed volume. In some embodiments, the expandible sample chamber is configured to be expanded from the collapsed volume to the expanded volume by communicating one or more gases into the collapsed volume within the flexible enclosure material. In some embodiments, the plurality of movable securing members are configured to be moved from a feedstock retaining configuration to a feedstock released configuration once the expandible sample chamber is expanded from the collapsed volume to the expanded volume.

According to another embodiment, a crystal growth furnace can be provided that comprises: an expandible sample container configured to be heated to between about 200° C. and about 6,000° C. to facilitate crystal growth from a volume of a crystal growth feedstock, wherein the expandible sample container is configured to be in a contracted configuration before and during transportation of the crystal growth furnace into a zero-gravity environment, the expandible sample container being further configured to transition from the contracted configuration to an expanded configuration once the crystal growth furnace is in the zero gravity environment and before the crystal growth; a crystal growth feedstock chamber positioned within the expandible sample container and configured to receive the volume of the crystal growth feedstock; and a plurality of feedstock securing members configured to secure the volume of the crystal growth feedstock within the crystal growth feedstock chamber when positioned in a securing configuration during transportation of the crystal growth furnace into the zero gravity environment, the plurality of feedstock securing members being further configured to transition from the securing configuration to a released configuration once the crystal growth furnace is in the zero gravity environment and before crystal growth.

In some embodiments, the crystal growth furnace can further comprise a thermocouple configured to communicate heat to at least a portion of the volume of the feedstock within the crystal growth feedstock chamber. In some embodiments, the expandible sample container is configured to be expanded from the contracted configuration to the expanded configuration by communicating one or more gases into the expandible sample container of the crystal growth furnace. In some embodiments, when the plurality of feedstock securing members are in the securing configuration, at least a portion of respective feedstock securing members of the plurality of feedstock securing members are in contact with an outside surface of the volume of the crystal growth feedstock in the crystal growth feedstock chamber within the expandible sample container. In some embodiments, when the plurality of feedstock securing members are in the released configuration, at least a portion of respective feedstock securing members of the plurality of feedstock securing members are maintained a non-zero distance from the outside surface of the volume of the crystal growth feedstock in the crystal growth feedstock chamber within the expandible sample container.

According to another embodiment, a method can be carried out that comprises disposing a volume of a crystal growth feedstock into a crystallization zone within a crystal growth furnace, the crystal growth furnace comprising a plurality of feedstock securing members being positioned in an open configuration; and transitioning the plurality of feedstock securing members from the open configuration to a closed configuration such that at least a distal portion of each of the plurality of feedstock securing members is releasably disposed against an outside surface of the volume of the crystal growth feedstock such that the volume of the crystal growth feedstock is securely retained within the crystallization zone of the crystal growth furnace. In some embodiments, the method can further comprise transporting the crystal growth furnace into a reduced gravity environment; and transitioning the plurality of feedstock securing members from the closed configuration to the open configuration such that the plurality of feedstock securing members are withdrawn from the crystallization zone within the crystal growth furnace.

According to another embodiment, a method can be carried out that comprises disposing a volume of a crystal growth feedstock into a crystallization zone within an expandable sample chamber within a crystal growth furnace, the crystal growth furnace comprising a plurality of feedstock securing members being positioned in an open configuration, the expandable sample chamber being in an expanded configuration; transitioning the plurality of feedstock securing members from the open configuration to a closed configuration such that at least a distal portion of each of the plurality of feedstock securing members is releasably disposed against an outside surface of the volume of the crystal growth feedstock such that the volume of the crystal growth feedstock is securely retained within the crystallization zone of the crystal growth furnace; and transitioning the expandable sample chamber from the expanded configuration to an unexpanded configuration. In some embodiments, the method can further comprise transporting the crystal growth furnace into a reduced gravity environment; and transitioning the plurality of feedstock securing members from the closed configuration to the open configuration such that the plurality of feedstock securing members are withdrawn from the crystallization zone within the crystal growth furnace.

In some embodiments, a plurality of sample containers can be provided that each contain a volume of crystal growth feedstock therein. The plurality of sample containers can be cycled through one or more crystallization zones and/or one or more of the plurality of sample containers can be cycled through a plurality of crystallization zones. In some embodiments, a sample changer or array of sample containers can be provided which can house the volumes of crystal growth feedstock(s) and can likewise house the grown crystals for retrieval by a sample retrieval vessel or the like.

According to another embodiment, a method can be carried out that comprises disposing a volume of a crystal growth feedstock into a crystallization zone within a crystal growth furnace, the crystal growth furnace comprising one or more inflatable securing members in a deflated configuration, wherein an outer surface of the one or more inflatable securing members are maintained a non-zero distance from an outer surface of the volume of the crystal growth feedstock in the crystallization zone when the one or more inflatable securing members are in the deflated configuration; and inflating the one or more inflatable securing members to transition the one or more inflatable securing members from the deflated configuration to an inflated configuration such that at least a portion of the outer surface of the one or more inflatable securing members abut at least a portion of the outer surface of the volume of the crystal growth feedstock. In some embodiments, the method can further comprise transporting the crystal growth furnace into a reduced gravity environment; and transitioning the plurality of inflatable securing members from the inflated configuration to the deflated configuration such that the plurality of inflatable securing members are withdrawn from the crystallization zone within the crystal growth furnace.

According to another embodiment, a method can be carried out that comprises communicating a volume of a crystal growth feedstock into a crystallization zone within an expandible sample container of a crystal growth furnace while the expandible sample container is in an expanded configuration; transitioning a plurality of feedstock securing members from a released configuration, in which a distal portion of each of the plurality of feedstock securing members are maintained a non-zero distance above an outside surface of the volume of the crystal growth feedstock, to a securing configuration, in which a distal portion of each of the plurality of feedstock securing members are maintained in securing contact with the outside surface of the volume of the crystal growth feedstock such that the volume of the crystal growth feedstock is retained within the crystallization zone within the expandible sample container of the crystal growth furnace during transportation of the crystal growth furnace into a zero-gravity environment; and transitioning the expandible sample container from the expanded configuration to a collapsed configuration before transportation of the crystal growth furnace into the zero-gravity environment. In some embodiments, the crystallization zone comprises a traveling solvent floating zone. In some embodiments, the crystal growth feedstock comprises a polycrystalline material.

According to another embodiment, a method can be carried out that comprises providing a crystal growth furnace comprising an expandible sample container in a collapsed configuration, the crystal growth furnace comprising a crystallization zone, and a volume of a crystal growth feedstock positioned within the crystallization zone, the crystal growth furnace further comprising a plurality of feedstock securing members positioned about the crystal growth feedstock in an inner volume of the expandible sample container and configured, in a securing configuration in which a distal portion of respective of the plurality of feedstock securing members are in securing contact with an outside surface of the volume of the crystal growth feedstock, to retain the volume of the crystal growth feedstock within the crystallization zone of the crystal growth furnace before and during transportation of the crystal growth furnace into a zero-gravity environment; transitioning the expandible sample container from the collapsed configuration to an expanded configuration; transitioning the plurality of feedstock securing members from the securing configuration to a released configuration in which the distal portion of respective of the plurality of feedstock securing members are maintained a non-zero distance above the outside surface of the volume of the crystal growth feedstock; heating at least a portion of the crystallization zone to form a hot zone (e.g., molten zone) within the volume of the crystal growth feedstock; while maintaining a temperature in the hot zone within a particular temperature range (such as a predetermined temperature range based on crystal growth feedstock composition, crystal growth furnace/technology being used, or the like), allowing deposition of the crystal growth feedstock onto one or more seed crystals positioned within the crystallization zone of the crystal growth feedstock; and allowing the crystallization zone to cool to a temperature below the particular temperature range to allow for formation of a monocrystalline structure from the crystal growth feedstock. In some embodiments, the hot zone can be a non-molten zone in which sublimation or annealing are conducted, allowing for migration of grain boundaries and the fixing of defects in the crystal growth without necessarily rising the temperature of the feedstock material in the hot zone to a melting temperature of the feedstock material.

According to other embodiments, an apparatus can be provided that comprises a processor and a memory storing instructions thereon that, when executed by the at least one processor, cause the apparatus to perform any of the methods described herein.

According to other embodiments, a computer program product can be provided that comprises a non-transitory computer readable storage medium storing instructions thereon that, when executed by a processor, cause performance of any of the methods described herein.

These and other aspects are described fully herein.

### BRIEF DESCRIPTION OF DRAWINGS

Some embodiments of apparatus and/or methods in accordance with embodiments of the present invention are now described, by way of example only, and with reference to the accompanying drawings, in which:

FIG. 1 illustrates a crystal growth feedstock securing device for a crystal growth furnace in a first configuration, in accordance with embodiments disclosed herein;

FIG. 2 illustrates a crystal growth feedstock securing device for a crystal growth furnace in a second configuration, in accordance with embodiments disclosed herein;

FIG. 3 illustrates a crystallization zone in a crystal growth furnace, in accordance with embodiments disclosed herein;

FIG. 4 illustrates a crystallization zone in a crystal growth furnace, in accordance with embodiments disclosed herein;

FIGS. 5A-5C illustrate a crystallization zone in a crystal growth furnace comprising a movable heating element for forming a hot zone in a crystal growth feedstock retained within the crystallization zone, in accordance with embodiments disclosed herein;

FIG. 6 illustrates a crystal growth furnace configuration, in accordance with embodiments disclosed herein;

FIG. 7 illustrates a crystal growth furnace configuration, in accordance with embodiments disclosed herein;

FIGS. 8A-8B illustrate a plurality of movable securing members for securing a crystal growth feedstock within a crystal growth furnace, with FIG. 8A illustrating the movable securing members in a first configuration and FIG. 8B illustrating the movable securing members in a second configuration, in accordance with embodiments disclosed herein;

FIG. 9 illustrates a movable securing member including a vibration damping member, in accordance with embodiments disclosed herein;

FIG. 10 illustrates a movable securing member including a vibration damping member, in accordance with embodiments disclosed herein;

FIG. 11 illustrates a crystallization zone within a feedstock container of a crystal growth furnace configured for retaining a crystal growth feedstock, the feedstock container comprising vibration damping members, in accordance with embodiments disclosed herein;

FIGS. 12A-12B illustrate an inflatable feedstock securing device for securing a crystal growth feedstock within a crystallization zone of a crystal growth furnace, with FIG. 12A illustrating the inflatable feedstock securing device in a deflated configuration and FIG. 12B illustrating the inflatable feedstock securing device in an inflated configuration, in accordance with embodiments disclosed herein;

FIG. 13 illustrates a crystallization zone within a feedstock container of a crystal growth furnace configured for retaining a crystal growth feedstock, the feedstock container comprising vibration damping members, in accordance with embodiments disclosed herein;

FIG. 14 illustrates a crystallization zone within a feedstock container of a crystal growth furnace configured for retaining a crystal growth feedstock, the crystal growth furnace comprising vibration damping members, in accordance with embodiments disclosed herein;

FIG. 15 illustrates a crystallization zone within a crystal growth furnace, the crystal growth furnace comprising vibration damping members at one or more feedstock retention points within the crystal growth furnace, in accordance with embodiments disclosed herein;

FIG. 16 illustrates a crystallization zone within a crystal growth furnace, the crystal growth furnace comprising movable securing members comprising one or more vibration damping members, in accordance with embodiments disclosed herein;

FIG. 17 illustrates an approach for controlling one or more operations of a crystal growth furnace, in accordance with embodiments disclosed herein;

FIG. 18 illustrates an approach for storage of one or more crystal growth furnaces in a payload delivery vessel, the crystal growth furnaces and/or the payload delivery vessel comprising one or more vibration dampers, in accordance with embodiments disclosed herein;

FIGS. 19A-19B illustrate a crystallization zone within a feedstock container of a crystal growth furnace comprising one or more inflatable securing members, with FIG. 19A illustrating the one or more inflatable securing members in a deflated configuration and with FIG. 19B illustrating the one or more inflatable securing members in an inflated configuration, in accordance with embodiments disclosed herein;

FIG. 20 illustrates an example computing device configured to carry out all or portions of methods for crystal growth, securing crystal growth feedstock, crystal growth feedstock release, and/or the like, in accordance with embodiments disclosed herein;

FIG. 21 illustrates an external computing device configured to carry out all or portions of methods for crystal growth, securing crystal growth feedstock, crystal growth feedstock release, and/or the like, in accordance with embodiments disclosed herein;

FIG. 22 is a block flow diagram illustrating a method for securing a crystal growth feedstock for transport to a zero-gravity or microgravity environment in a sample chamber of a crystal growth furnace, in accordance with embodiments disclosed herein;

FIG. 23 is a block flow diagram illustrating a method for releasing a crystal growth feedstock secured for transport to a zero-gravity or microgravity environment in a sample chamber of a crystal growth furnace, in accordance with embodiments disclosed herein; and

FIG. 24 is a block flow diagram illustrating a method for growing crystals in a zero-gravity or microgravity environment, in accordance with embodiments disclosed herein.

### DETAILED DESCRIPTION

Terrestrial crystal growth of high-quality crystals is limited by factors such a gravity-based convection, acoustic and vibratory perturbations, crystal growth rate requirements, and other environmental and process-related factors that lead to imperfections such as stress-induced impurities, uneven crystal structure, a polycrystalline macrostructure, and other undesirable characteristics. In recent years, there have been attempts to grow crystals in zero gravity or microgravity environments to reduce or eliminate gravity-related convection and other perturbations that can negatively affect crystal growth. For example, the International Space Station National Laboratory has carried out micro-scale and benchtop-scale crystal growth experiments in zero-gravity and microgravity environments aboard the International Space Station as it orbits Earth. These experiments were mainly focused on crystals of organic molecules, such as proteins and amino acids, for pharmaceutical production in space, and crystals of inorganic molecules for optics and electronics. These experiments illustrated how crystals grown in microgravity grow in a more uniform manner, can be grown larger without experiencing imperfections due to the lower probability of imperfections during crystal growth, and can be grown more slowly, which may lead to increased crystal structure quality.

While a zero-gravity or microgravity environment can provide a convection-free, quiescent environment for crystal growth, the process of loading crystal growth feedstock into a crystal growth furnace terrestrially (on Earth) and transporting the crystal growth furnace into orbit (e.g., to the International Space Station or another satellite, such as a manufacturing satellite), is a process which incurs or induces many direct or indirect stresses on the crystal growth feedstock. For example, the crystal growth furnace is often carried into orbit as payload of a rocket, which experiences many vibrations, loud noises, increased heat, temperature fluctuations, and other launch-related stresses. Once in orbit, the payload vehicle must typically orient itself and move into a stable orbit about Earth or another planetary body, and then must dock with the satellite, such as the International Space Station or a manufacturing satellite. Each of the launch, fuel stage release, payload vehicle orientation in orbit, and payload vehicle docking processes incur additional vibratory and acoustic impingements into the crystal growth feedstock, which can further affect the eventual quality of the crystal grown from the crystal growth feedstock. Such transportation-related stresses lead to imperfections and impurities in the crystal grown from that crystal growth feedstock, even though the crystal growth process is carried out in a convection-free, quiescent environment, such as a zero-gravity or microgravity environment.

As such, there is a need for improved methods and devices for securing crystal growth feedstock during launch, fuel stage release, orientation in orbit, and payload vehicle docking to reduce or eliminate such transportation-related stresses on the crystal growth feedstock.

Further, there is a need for improved methods and devices for releasing secured crystal growth feedstock once the crystal growth furnace is aboard the satellite and before crystal growth commences.

Also, there is a need for improved methods and devices for crystal growth in zero-gravity or microgravity environments.

The present disclosure more fully describes various embodiments, with reference to the accompanying drawings, related to crystal growth in zero-gravity or microgravity, and related to methods and devices for securing and releasing crystal growth feedstock to address these and other needs. It should be understood that some, but not all, embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments of the present disclosure will now be described more fully hereinafter with reference to the accompanying drawings, in which some, but not all embodiments of the disclosed systems, methods, and apparatuses are shown. Indeed, the disclosed systems, methods, and apparatuses may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “exemplary” are used to be examples with no indication of quality level. Like numbers refer to like elements throughout.

As used herein, the terms “instructions,” “file,” “designs,” “data,” “content,” “information,” and similar terms may be used interchangeably, according to some example embodiments of the present disclosure, to refer to data capable of being transmitted, received, operated on, displayed, and/or stored. Thus, use of any such terms should not be taken to limit the spirit and scope of the disclosure. Further, where a computing device is described herein to receive data from another computing device, it will be appreciated that the data may be received directly from the other computing device or may be received indirectly via one or more computing devices, such as, for example, one or more servers, relays, routers, network access points, base stations, and/or the like.

As used herein, the term “computer-readable medium” refers to any medium configured to participate in providing information to a processor, including instructions for execution. Such a medium may take many forms, including, but not limited to a non-transitory computer-readable storage medium (for example, non-volatile media, volatile media), and transmission media. Transmission media include, for example, coaxial cables, copper wire, fiber optic cables, and carrier waves that travel through space without wires or cables, such as acoustic waves and electromagnetic waves, including radio, optical, and infrared waves. Signals include man-made transient variations in amplitude, frequency, phase, polarization, or other physical properties transmitted through the transmission media. Examples of non-transitory computer-readable media include a floppy disk, a flexible disk, hard disk, magnetic tape, any other non-transitory magnetic medium, a compact disc read only memory (CD-ROM), compact disc compact disc-rewritable (CD-RW), digital versatile disc (DVD), Blu-Ray, any other non-transitory optical medium, punch cards, paper tape, optical mark sheets, any other physical medium with patterns of holes or other optically recognizable indicia, a random access memory (RAM), a programmable read only memory (PROM), an erasable programmable read only memory (EPROM), a FLASH-EPROM, any other memory chip or cartridge, a carrier wave, or any other non-transitory medium from which a computer can read. Other example memory devices use quantum data storage (solid state devices using quantum mechanics) in which a probability density/cloud is expanded by power change at a gate to ‘store’ an electron spin direction probability state (superposition) within a charge trap behind a dielectric insulative barrier in one of a plurality of memory cells within a chiplet of a memory cell. The term computer-readable storage medium is used herein to refer to any computer-readable medium except transmission media. However, it will be appreciated that where embodiments are described to use a computer-readable storage medium, other types of computer-readable mediums may be substituted for or used in addition to the computer-readable storage medium in alternative embodiments. By way of example only, a design file for a printed article may be stored on a computer-readable medium and may be read by a computing device, such as described hereinbelow, for controlling part or all of crystal growth processes and associated furnaces, sample containers, feedstock containers, and other apparatuses and components thereof, according to various embodiments described herein.

As used herein, the term “circuitry” refers to all of the following: (a) hardware-only circuit implementations (such as implementations in only analog and/or digital circuitry); (b) to combinations of circuits and computer program product(s) comprising software (and/or firmware instructions stored on one or more computer readable memories), such as (as applicable): (i) to a combination of processor(s) or (ii) to portions of processor(s)/software (including digital signal processor(s)), software, and memory(ies) that work together to cause an apparatus, such as a mobile phone or server, to perform various functions described herein); and (c) to circuits, such as, for example, a microprocessor(s) or a portion of a microprocessor(s), that require software or firmware for operation, even if the software or firmware is not physically present. This definition of “circuitry” applies to all uses of this term in this application, including in any claims. As a further example, as used in this application, the term “circuitry” would also cover an implementation of merely a processor (or multiple processors) or portion of a processor and its (or their) accompanying software and/or firmware. The term “circuitry” would also cover, for example and if applicable to the particular claim element, a baseband integrated circuit or applications processor integrated circuit for a mobile phone or a similar integrated circuit in a server, a cellular network device, other network device, and/or other computing device.

As used herein, the term “computing device” refers to a specialized, centralized device, network, or system, comprising at least a processor and a memory device including computer program code, and configured to provide guidance or direction related to the charge transactions carried out in one or more charging networks.

As used herein, the terms “about,” “substantially,” and “approximately” generally mean plus or minus 50% of the value stated, e.g., about 200 μm would include 100 μm to 300 μm, about 1,000 μm would include 500 μm to 1,500 μm. Any provided value, whether or not it is modified by terms such as “about,” “substantially,” or “approximately,” all refer to and hereby disclose associated values or ranges of values thereabout, as described above.

As used herein, “and/or” refers to and encompasses any and all possible combinations of one or more of the associated listed items, as well as the lack of combinations when interpreted in the alternative (“or”).

As used herein, conditional language used herein, such as, among others, “can,” “could,” “might,” “may,” “e.g.,” and the like, unless specifically stated otherwise or otherwise understood within the context as used, is generally intended to convey that certain examples include, while other examples do not include, certain features, elements and/or steps. Thus, such conditional language is not generally intended to imply that features, elements and/or steps are in any way required for one or more examples or that one or more examples necessarily include logic for deciding, with or without author input or prompting, whether these features, elements and/or steps are included or are to be performed in any particular example. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

In some embodiments, a crystal growth furnace (furnace assembly) can be provided for growing crystals in reduced gravity environments (e.g., less-than-Earth gravity, microgravity, zero-gravity, etc.) that possesses the ability to survive the rigors of transportation and operation aboard a spacecraft. Existing furnaces are designed for growing crystals in highly controlled terrestrial laboratory environments. However, such existing furnaces are not designed for space travel and operation and are therefore not configured to withstand the variety of forces experienced during transit, are not configured to handle extreme temperature swings, are not able to cool a grown crystal in a vacuum, and are not configured to facilitate remote sample preparation. Described herein are systems, methods, apparatuses, and computer program products for crystal growth furnaces and components thereof that are dimensioned and configured to withstand transit forces, temperature swings, cooling in a vacuum, and remote sample preparation, among other features and characteristics.

In some embodiments, a crystal growth furnace can comprise multiple furnaces capable of growing crystals while subjected to the rigors and forces of space travel. A number of systems, devices, methods, and computer program products are described herein that are configured to facilitate higher-quality crystal growth in reduced gravity environments than what is currently possible in terrestrial environments and increase the quality of commercially available crystals.

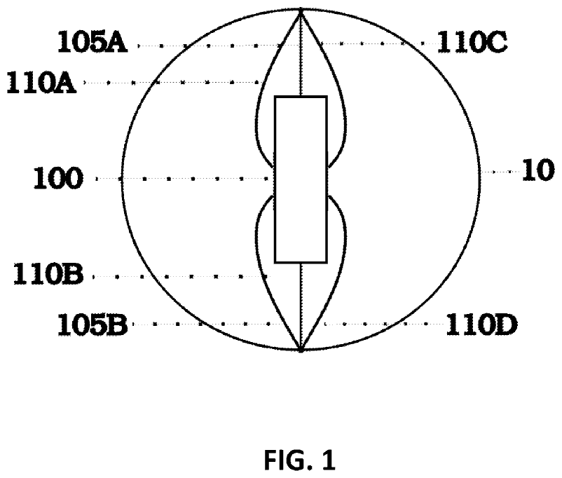

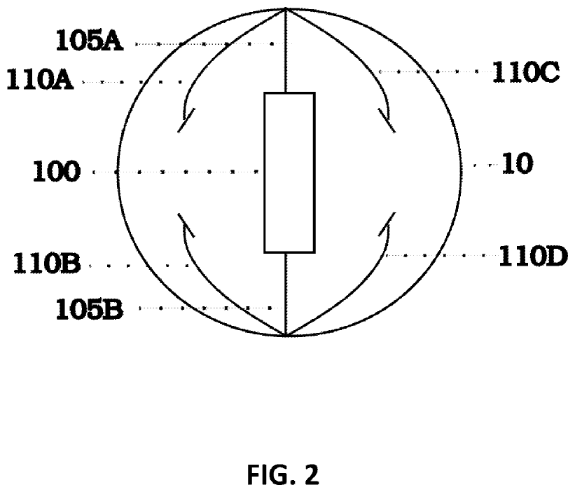

FIGS. 1 and 2 illustrate a feedstock container 10 configured for use in a crystal growth furnace 1. The feedstock container 10 can be configured for retaining therein a volume of a crystal growth feedstock 100. The feedstock container 10 further comprises feedstock retention points 105A, 105B. The feedstock retention points 105A, 105B are configured to retain the volume of the crystal growth feedstock 100. In some embodiments, the feedstock container 10 can comprise two feedstock retention points 105A, 105B that are configured to be in contact with a proximal portion of the crystal growth feedstock 100 and a distal portion of the crystal growth feedstock 100.

The feedstock container 10 further comprises a plurality of movable securing members 110A, 110B, 110C, 110D. In some embodiments, the plurality of movable securing members 110A, 110B, 110C, 110D can include two, three, four, or more movable securing members, arms, supports, appendages, or the like.

As illustrated in FIG. 1, the plurality of movable securing members 110A, 110B, 110C, 110D can comprise an elongated member attached within the feedstock container 10 at a pivot point and including a contact point at a distal portion of the elongated member.

As illustrated in FIG. 1, the plurality of movable securing members 110A, 110B, 110C, 110D are in a first configuration, also called a ‘secured configuration’ herein. In the first configuration, the plurality of movable securing members 110A, 110B, 110C, 110D are actuated in a first direction about the pivot points until the contact point at the distal portion of the elongated member is maintained in contact with an outer surface of the volume of the crystal growth feedstock 100.

As illustrated in FIG. 2, the plurality of movable securing members 110A, 110B, 110C, 110D are in a second configuration, also called a ‘released configuration’ herein. In the second configuration, the plurality of movable securing members 110A, 110B, 110C, 110D are actuated in a second direction about the pivot points until the contact point at the distal portion of the elongated member is maintained a non-zero distance from the outer surface of the volume of the crystal growth feedstock 100.

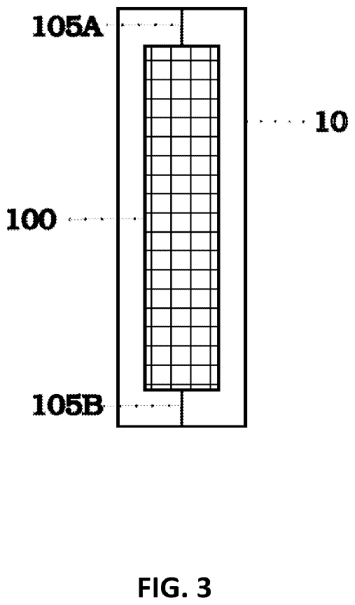

FIG. 3 illustrates an alternative configuration of the feedstock container 10 comprising the feedstock retention points 105A, 105B that are configured to be in contact with a proximal portion of the crystal growth feedstock 100 and a distal portion of the crystal growth feedstock 100. In some embodiments, the crystal growth feedstock 100 can comprise one or more pure elements, minerals, metals, intermetallic compounds, inorganic materials, organic materials, or combinations thereof. In some embodiments, the crystal growth feedstock 100 can comprise one or more of: gallium, zinc, cadmium, rutile, indium, silicone, germanium, molybdenum, tungsten, copper, titanium, graphene, aluminum, tin, antimony, manganese, magnesium, iodine, combinations thereof, and/or the like. In some embodiments, the crystal growth feedstock 100 can be heated and subsequently cooled form a crystal having low or minimal impurities. In some embodiments, the crystal can be formed from the crystal growth feedstock 100 using a crystal growth furnace. In some embodiments, the crystal formed from the crystal growth feedstock 100 can be used for applications including semiconductors, superconductors, optics, photonics, magnetic systems, analytical chemistry, imaging, piezoelectrics, electronic devices, ferroelectrics, and/or the like.

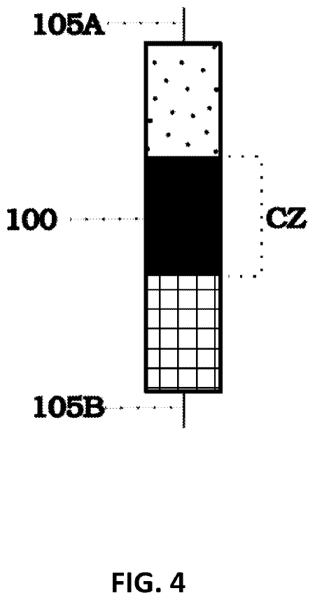

FIG. 4 illustrates various zones within the crystallization zone in a crystal growth furnace. As illustrated in FIG. 4, the crystal growth feedstock 100 is heated along a length of the crystal growth feedstock 100 in a sequential or sweeping fashion. In some embodiments, the heating can comprise heating one or more portions of the crystal growth feedstock 100 based upon a particular ramp rate, a particular temperature or temperature range, a cooling rate, and/or the like. In some embodiments, a heating element (not shown) can be moved along a length of the crystal growth feedstock 100 at a rate that is needed for the suitable heating of one or more portions of the crystal growth feedstock 100. As illustrated in FIG. 4, an active crystallization zone CZ can be formed by heating a particular portion of the crystal growth feedstock 100, with a crystal formation portion forming above the CZ based on the heating and subsequent cooling of the crystal formation portion, the CZ being a hot zone (e.g., molten zone), and a remaining feedstock portion in an amorphous or polycrystalline state being located below the CZ. As illustrated in FIG. 4, a direction of movement of the hot zone is from 105A to 105B. However, the direction of movement of the hot zone can be from 105B to 105A such that the crystal formation portion is formed below the CZ while the remaining feedstock portion is located above the CZ.

In some embodiments, the hot zone can be a molten zone, such as when Czochralski method crystal growth is used, during which a crystal is ‘pulled’ from a molten zone or feedstock melt. The shape of such a crystal may be controlled by one or multiple different variables, such as temperature gradient, a die that is held in contact with the melt, and/or the like.

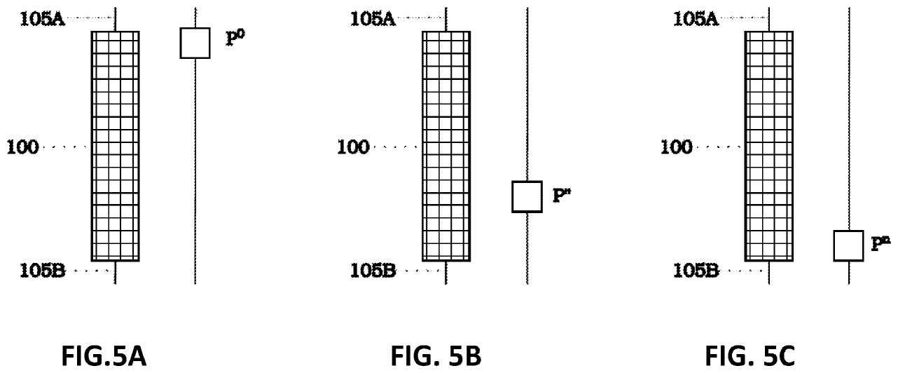

FIGS. 5A-5C illustrate a process for crystal growth from the crystal growth feedstock 100 based upon movement of a heating element from a first position P° to a final position Pⁿ, with one or more interstitial positions P″ being defined therebetween along the length of the crystal growth feedstock 100 between 105A and 105B. As shown in FIGS. 5A-5C, the direction of travel of the heating element is from top to bottom, between 105A and 105B, however the direction of travel of the heating element can alternative be from bottom to top, between 105B to 105A.

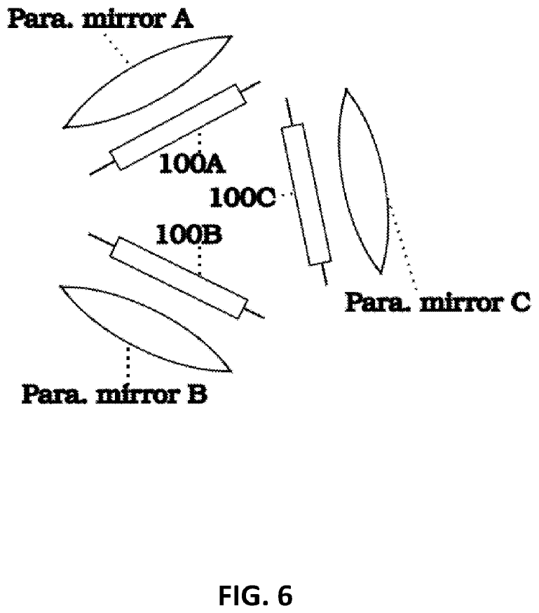

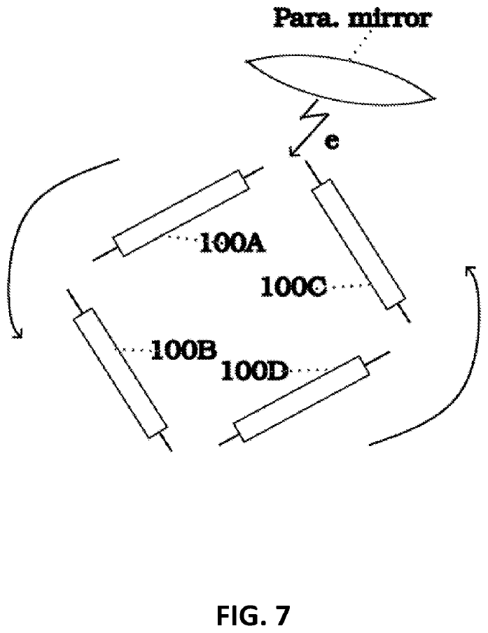

FIG. 6 illustrates a crystal growth furnace configuration in which a plurality of sample containers 100A, 100B, 100C are arranged in line with, respectively, a plurality of parabolic mirrors. While FIG. 6 illustrates a crystal growth furnace having a ratio of sample containers 100A, 100B, 100C. to parabolic mirrors of 1:1, the ratio of sample containers 100A, 100B, 100C to parabolic mirrors can be 2:1, 3:1, 1:2, 1:3, or any other suitable ratio. For example, in FIG. 7, a crystal growth furnace configuration is illustrated in which the ratio of sample containers 100A, 100B, 100C, 100D to parabolic mirrors is 4:1. In such an arrangement, the parabolic mirror(s) may be configured to move relative to the sample containers 100A, 100B, 100C, 100D, and/or the sample containers 100A, 100B, 100C, 100D can be configured to move relative to the parabolic mirror(s) such that the duration of focused energy/heat directed at crystal growth feedstock in each of the sample containers 100A, 100B, 100C, 100D can be adjusted in order to achieve a suitable temperature, heating ramp rate, cooling ramp rate, and/or the like for crystal formation from the crystal growth feedstock.

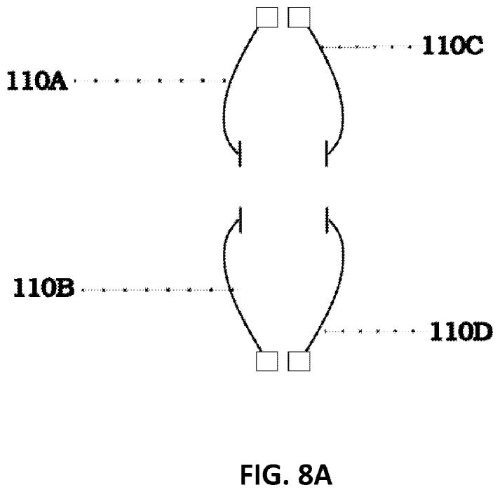

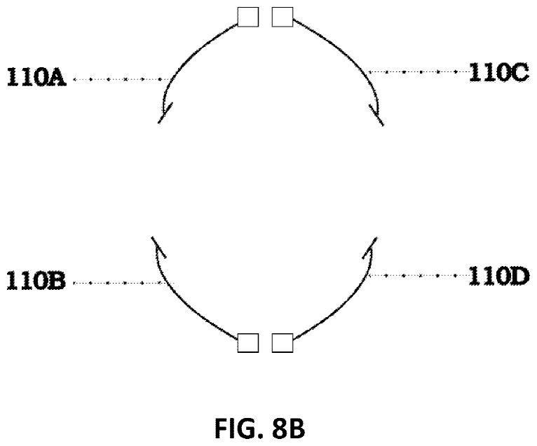

FIGS. 8A-8B illustrate configurations for the plurality of movable securing members 110A, 110B, 110C, 110D for securing the crystal growth feedstock 100 within the crystal growth furnace 1. FIG. 8A illustrates the movable securing members 110A, 110B, 110C, 110D in a first configuration and FIG. 8B illustrates the movable securing members 110A, 110B, 110C, 110D in a second configuration. In the first configuration, the movable securing members 110A, 110B, 110C, 110D are positioned in a secured configuration. The movable securing members 110A, 110B, 110C, 110D can comprise a pivot portion configured to be attached inside the sample container 10 or attached inside the crystal growth furnace 1. For example, the movable securing members 110A, 110B, 110C, 110D can be coupled at the pivot portion to an inside wall of the sample container 10 or an inside wall of the crystal growth furnace 1. In some embodiments, the movable securing members 110A, 110B, 110C, 110D can comprise a longitudinal portion (also referred to as an “elongated portion” or an “arm” herein). The pivot point can be coupled (e.g., removably coupled) to the longitudinal portion at a proximal end of the longitudinal portion. In some embodiments, the longitudinal portion can be a set length based on the dimensions (e.g., length, width, depth, diameter, aspect ratio, etc.) of the crystal growth feedstock 100. In some embodiments, the longitudinal portion can be adjustable in order to accommodate crystal growth feedstock 100 having different dimensions.

In some embodiments, each of the movable securing members 110A, 110B, 110C, 110D can further comprise a contact portion formed at, or coupled to, the longitudinal portion at a distal end of the longitudinal portion, the distal end being opposite the proximal portion. The contact portion of each of the movable securing members 110A, 110B, 110C, 110D can be dimensioned and configured to be placed in contact with an outer surface of the crystal growth feedstock 100. When the movable securing members 110A, 110B, 110C, 110D are positioned in the first configuration, the crystal growth feedstock 100 can be retained within the feedstock container 10 of the crystal growth furnace 1.

As illustrated in FIG. 8B, the movable securing members 110A, 110B, 110C, 110D are transitioned from the first configuration to the second configuration (also referred to as an “open configuration” or a “released configuration” herein). In the second configuration, the movable securing members 110A, 110B, 110C, 110D are rotatably moved about the pivot portions to establish a non-zero distance between the contact portion at the distal end of each longitudinal portion of the moveable securing members 110A, 110B, 110C, 110D and the outer surface of the crystal growth feedstock 100.

In some embodiments, such as when the crystal growth furnace 1 is configured for operation in a reduced gravity environment, such as a microgravity environment or a zero-gravity environment, the movability of the movable securing members 110A, 110B, 110C, 110D can facilitate disposing the crystal growth feedstock 100 into the feedstock container 10 within the crystal growth furnace 1. The movable securing members 110A, 110B, 110C, 110D can be moved to the second configuration before loading the crystal growth feedstock 100 into the feedstock container 10 of the crystal growth furnace 1. After loading the crystal growth feedstock 100 into the feedstock container 10 of the crystal growth furnace 1, the movable securing members 110A, 110B, 110C, 110D can be transitioned from the second configuration to the first configuration by moving the contact portions at the distal portions of the longitudinal portion into contact with an outer surface of the crystal growth feedstock 100. By maintaining the contact portions at the distal portions of the longitudinal portion into contact with the outer surface of the crystal growth feedstock 100, the movable securing members 110A, 110B, 110C, 110D can retain the crystal growth feedstock 100 in place within the feedstock container 10 of the crystal growth furnace 1 before and during transportation of the crystal growth furnace 1 from a terrestrial environment to the reduced gravity environment.

By retaining the crystal growth feedstock 100 securely within the feedstock container 10 of the crystal growth furnace 1, there is an increased likelihood that the crystal growth feedstock 100 is not damaged by the vibrational, acoustic, thermal, and/or other perturbations that would otherwise be incurred during loading of the crystal growth furnace 1 into a payload launch vehicle or the like, during launch into orbit about Earth or another planetary body, and/or during docking of the payload launch vehicle with a manufacturing satellite, a planetary body, and/or the like.

Once the crystal growth furnace 1 is transported from the terrestrial environment to the reduced gravity environment, the movable securing members 110A, 110B, 110C, 110D can be transitioned from the first configuration to the second configuration to release the crystal growth feedstock 100 and move the movable securing members 110A, 110B, 110C, 110D away from the outer surface of the crystal growth feedstock 100. The extent of rotation of the movable securing members 110A, 110B, 110C, 110D about the pivot points achieves a desired distance between the contact portions of the movable securing members 110A, 110B, 110C, 110D and the outer surface of the crystal growth feedstock 100, such as to accommodate the crystal growth process of the crystal growth feedstock 100 to form the crystal.

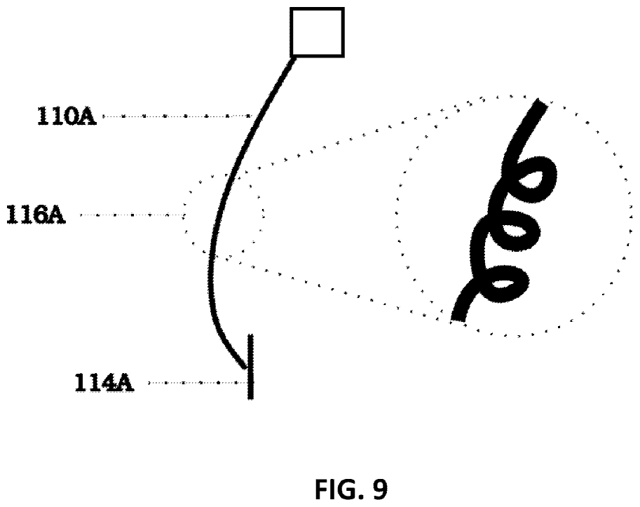

FIG. 9 illustrates an embodiment of the movable securing member 110A including a vibration damping member 116A, in accordance with embodiments disclosed herein. The movable securing member 110A can be dimensioned and configured such that the vibration damping member 116A is positioned along the longitudinal portion between the pivot portion 112A and the contact portion 114A at the distal end of the longitudinal portion. The vibration damping member 116A can be or comprise an active or passive damping device. For example, the vibration damping member 116A can be or comprise a spring, a viscous fluid damping device, a magnetic flux damper, a vidscoelestic damper, such as a Sorbothane® vibration damper, an electromagnetic induction damper, a pneumatic damper, other suitable damping devices, and/or the like.

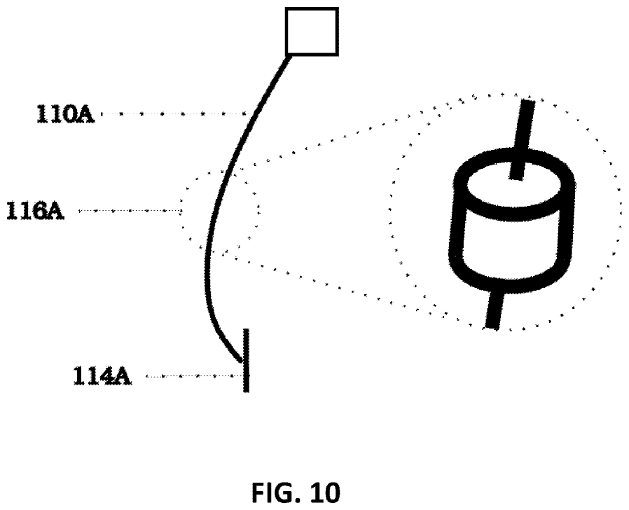

FIG. 10 illustrates an embodiment of the movable securing member 110A in which the vibration damping member 116A is or comprises an active vibration damping device. In some embodiments, the active vibration damping device can be positioned between the pivot portion 112A and the contact portion 114A at the distal end of the longitudinal portion.

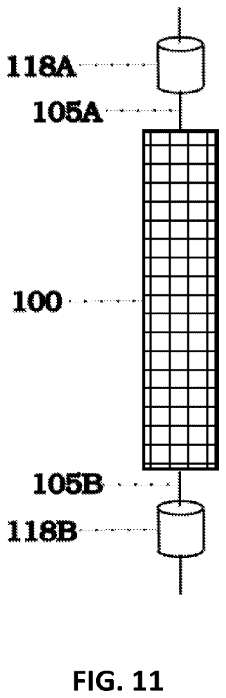

FIG. 11 illustrates an embodiment of the feedstock container 10 in a crystal growth furnace 1 in which active damping devices 118A, 118B are positioned between the crystal growth feedstock 100 and the feedstock retention points 105A, 105B in the feedstock container 10.

In an example, a crystal growth furnace (e.g., 1) can be used to grow a gallium nitride crystal in a zero-gravity environment. The crystal growth furnace can employ traveling solvent floating zone crystal growth, which may reduce the impact of convective currents in both the atmosphere and the hot zone (e.g., CZ).

Without wishing to be bound by any particular theory, using polycrystalline gallium nitride (GaN) as a feedstock may allow for a stoichiometric amount of nitrogen to be located directly at the interface where dissolution is happening and negates the need for nitrogen diffusion over the long length-scales associated with the boule diameter. This is not to preclude approaches where that diffusion is utilized under different growth conditions. To prepare for this, a sample is prepared terrestrially and packaged in such a way so as to survive transportation.

This can be carried out using an inflatable or movable securing member (e.g., 110, 210), such as described elsewhere herein. In one configuration, a seed crystal may be “glued” to a larger polycrystalline cylinder of GaN with a section of elemental sodium (optionally containing some gallium). This entire assembly will be held with multiple retractable arms possessing articulating joints. Once the crystal growth furnace (e.g., 1) reaches the reduced gravity environment (e.g., orbit about Earth), those same arms may be used to orient/align the sample within the sample chamber. At opposite ends of the chamber, it is important to have mount points to delicately hold each end of the sample. During growth, there will be a hot zone (e.g., molten zone) suspended between the two pieces which is held in place only by surface tension. Therefore, these mounting points need to avoid transferring vibrations into the growing crystal and may employ magnetic or polymer dampeners to absorb those. Those mount points may use the ability to increase or decrease the distance between the two ends or rotate to manipulate the crystal growth.

Once in the reduced gravity environment, this hot zone may be achieved through the application of directed energy, inductive heating, or both in a compatible atmosphere (referred to here as “heating element(s)” for simplicity). The heating elements will similarly be aligned relative to the sample in preparation of the growth and to counteract shifting during transport. This simple example will focus on inductive heating under a nitrogen atmosphere of between about 5 bar and about 50 bar. The conductive section comprised of sodium can be selectively heated between the two non-conductive sections of GaN. The specific temperature of the sodium melt will be monitored by thermal camera or pyrometer. Visible light cameras will also be used for monitoring. Temperatures for this approach are expected to be in the range of between about 700° C. and about 950° C. While some mass loss is expected, the reduction of convective currents is anticipated to reduce this as compared to terrestrial applications of related techniques.

When heated and in an equilibrium state, the heating elements will be moved away from the seed crystal at a very slow rate (e.g., about 0.01 mm/hr to about 10 mm/hr) to encourage movement of the hot zone and deposition of material to grow the seed crystal. The elements may be moved by careful rotation of a screw and monitored with either a rotary or linear encoder. Re-crystallization on the seed crystal requires a significant amount of thermal energy to be dissipated by the seed holder—possibly >500 W depending on the growth size. Therefore compatible materials (e.g., ceramics and metals), active cooling, and a liberal application of heat pipes may be needed to disperse that and safely radiate it away. The same may be applied to the heating elements and supporting electronics depending on the growth size.

At the conclusion of a growth, the power will be ramped down and the two ends of the sample manipulated so as to avoid thermal shock or cracking of the grown crystal due to differences in the thermal expansion of the dissimilar materials.

When cool, the sample will again be stabilized for transport. This may be with the same arms used to hold the sample initially, “airbags” inflated to prevent movement, or some combination. This stabilized sample container may then be transferred for retrieval or the whole furnace assembly may be transported.

In some embodiments, the crystal growth furnace 1 can comprise an aluminum or titanium frame. In some embodiments, once the crystal growth furnace 1 is disposed in the reduced gravity environment, it may be configured to recycle heat with heat exchangers on any gas flows. If operating at relatively higher temperatures, materials such as ceramic and metallic materials may be used. In some embodiments, one or multiple active and passive cooling solutions can be used to route and radiate heat from the crystal growth furnace 1. In some embodiments, the crystal growth furnace 1 can be at least partially integrated with heating, cooling, gas supply, electrical, or other processes streams and in situ systems in a manufacturing satellite or the like in the reduced gravity environment.

In some embodiments, redundant safety systems can be included with the crystal growth furnace 1 or provided by the manufacturing satellite or the like upon transportation of the crystal growth furnace 1 thereto. Such safety systems can include systems for venting of hazardous materials, excess temperature, waste materials, unused feedstock, overpressure conditions, and/or the like. Such safety systems can also comprise secondary containment.

In some embodiments, the crystal growth furnace 1 can comprise a variable number of posts to accommodate different crystal growth feedstock 100 sizes and different sizes of grown crystal. In some embodiments, the crystal growth furnace 1 can comprise one or a plurality of sample chambers (e.g., being greater than about 4 inches to about 6 inches in diameter) to support crystal growth needs for semiconductor wafers and other applications.

In some embodiments, the crystal growth furnace 1 can comprise one or more cameras configured to capture and cache video from within the feedstock container 10 and/or crystallization zone. Captured video can be transmitted as feedback signals to a remote (terrestrial or extraterrestrial) control center/device configured to tune crystal growth processes in the crystal growth furnace 1 based on crystal growth performance from the captured video. Additionally or alternatively, the captured video can be processed locally using computer vision algorithm(s), image processing algorithm(s), and/or machine learning algorithm(s)/model(s) to determine crystal growth performance and locally control operation of the crystal growth furnace 1.

In some embodiments, various components of the crystal growth furnace 1 can be made from materials capable of thermal cycling across an extreme temperature range. In some embodiments, the crystal growth furnace 1 can be high vacuum compatible, may comprise an open frame, and/or may use only cryogenic and high vacuum greases and seals in order to facilitate operation in extreme temperature environments, extreme gravitational environments, extreme radiological environments, extreme pressure environments, and/or the like. Fluidic dampeners, hydraulic dampeners, pneumatic dampeners, mechanical dampeners, electromagnetic dampeners, and/or magnetic dampeners may be leveraged to reduce vibrations.

In some embodiments, a manufacturing satellite configured to receive a crystal growth furnace 1 can be configured for, e.g., encrypted communication with a remote terrestrial or extraterrestrial station or control device, heat dissipation of greater than about 2 kW, interchangeability of crystal growth furnaces 1 and feedstock containers 10 (whether the same or different dimensions and form factors), an ability to be de-orbited in an emergency, a capability for grown crystal samples to be secured and packaged for de-orbit or for payload vessel re-entry to Earth, and/or the like.

In some embodiments, the crystal growth furnace 1 can be or comprise a floating zone crystal growth furnace, a traveling solvent crystal growth furnace, a sublimation crystal growth furnace, a reactive gas (e.g., showerhead) crystal growth furnace, a halide vapor phase epitaxy crystal growth furnace, an inert gas crystal growth furnace, an ammonia-thermal/hydrothermal (liquid/supercritical) crystal growth furnace, an evaporation crystal growth furnace, and/or the like.

In some embodiments, the floating zone can be LED, laser, halogen, arc lamp, or solar concentrator (via large fresnel lens sheet, tunable based on rolling/unrolling area). Induction can be used with a conductive traveling solvent flux, or by heating of applicable materials to the point where they are sufficiently conductive. A material example (in a very different furnace geometry) can be seen with cubic zirconia in a skull crucible.

In some embodiments, application of a sample geometry with a middle cone area/constriction can be employed to encourage growth of the single crystal. In some embodiments, the crystal growth furnace 1 can be configured to employ one or more of a variety of sample centering approaches, such as acoustics, gas jets directed at the sample, induction/magnetic centering, or via surface tension with the seed crystal by retracting the arms used to hold the sample during transit.

In some embodiments, the crystal growth furnace 1 can comprise one or more remote visualization and alignment devices (not shown), such as pyrometers, thermal cameras, optical cameras with various filters. In one example, band pass filters may be selected to correspond with specific material properties. In some embodiments, a shutter system may be used between a remote visualization device (e.g., camera) and the sample container 10 whereby when the shutter is in an open configuration images may be captured of the feedstock/sample in the crystallization zone (e.g., CZ), while closure of the shutter protects the remote visualization device and other components of the crystal growth furnace 1 from damage due to high temperatures, high pressures, exposure to undesirable materials, etc.

In some embodiments, the crystal growth furnace 1 can be configured to incorporate ammonia hardware with spacecraft/manufacturing satellite cooling infrastructure, such as when the crystal growth furnace 1 is a reactive gas crystal growth furnace or an ammoniathermal crystal growth furnace. In some embodiments, the crystal growth furnace 1 can comprise systems for radiative cooling of critical parts (e.g., seals), can include one or more heat exchangers to facilitate cooling of grown crystals, and may include minimal or no glass components due to vibration risks associated therewith. In some embodiments, the crystal growth furnace 1 can leverage the hard/absolute vacuum of space to bake out the sample container (e.g., feedstock container 10) with heaters or solar radiation. In some embodiments, the crystal growth furnace 1 can leverage the hard vacuum of space for annealing grown crystals. In some embodiments, the crystal growth furnace 1 can be oxygen-free.

In some embodiments, the crystal growth feedstock 100 can be failed crystals or offal/waste from previous crystal growth processes, a polycrystalline rod, a terrestrially produced and sintered rod, and/or the like.

In some embodiments, each inflatable or movable securing member/mechanism may have a stabilized “home” position to which it returns before, during, and/or after crystal growth. The crystal growth furnace 1 may include sensors or other devices to facilitate remote determination of a current position for each inflatable or movable securing member. Sensors such as force sensors can be positioned in the feedstock container 10 on an opposite side of an inflatable securing member/mechanism from the crystal growth feedstock 100 such that the force being exerted on the outer surface of the crystal growth feedstock 100 by the inflatable securing member/mechanism when in the inflated configuration can be determined or approximated by the force exerted on the force sensor.

Additionally or alternatively, other sensors, sensing devices, optical analysis devices, and/or the like can be included in the crystal growth furnace 1 to sporadically, iteratively, or continuously analyze/test for feedstock or crystal morphology, form factor, crystallinity, dimensions, shape, growth rate, and/or the like. Other sensors or devices can be used to analyze the hot zone/molten zone, including size, shape, temperature ramp rate, and/or the like. Such devices may include optical sensors, temperature sensors, pyrometers, and/or the like. The feedback information, data, images, or the like that are produced by using such devices can be maintained locally at the crystal growth furnace 1 and used for in situ control (e.g., using a Proportional-Integral-Derivative [PID] controller or the like) and/or can be provided to a remote-control center or device, such as terrestrial control center or the like. However, in some instances, remote control, which requires that such feedback data is provided to the remote-control center or device, which is used to prepare process control instructions or furnace parameter change instructions which are then sent back to the crystal growth furnace 1, can incur unwanted signaling and control feedback latency. Local control can be carried out, based on such feedback data, using a local processing or computing device managing a machine learning model or artificial intelligence program or the like, which may reduce signaling latency and reduce the time between analysis/imaging and process control changes at the crystal growth furnace 1.

Without wishing to be bound by any particular theory, sample growth may not necessarily need to be constrained within a glass or ceramic tube as convection if not a problem. Instead, in some embodiments, the crystal growth furnace 1 may not include a feedstock container 10, per se, but instead may include a crystallization zone within which the crystal growth feedstock 100 is disposed. A tube might only be necessary when the experimental conditions must be more rigorously constrained.

In some embodiments, the feedstock container 10 can be configured to be modular, such that it can be removed from the crystal growth furnace 1 or moved to a storage space within the crystal growth furnace 1 after completion of crystal growth from the crystal growth feedstock 100 therein. Likewise, after removal or storage of the modular feedstock container 10 following growth of a crystal therein, a new modular feedstock container 10 comprising therein a new crystal growth feedstock 100 can be loaded into the crystal growth furnace 1 or moved from a staging area within the crystal growth furnace 1 in order for the crystal growth furnace 1 to carry out crystal growth from the new crystal growth feedstock 100 in the new feedstock container 10.

In some embodiments, after a crystal is grown from crystal growth feedstock 100 in a feedstock container 10, the feedstock container can be known/referred to as a sample container. After crystal growth, sample containers can be moved from the crystal growth furnace 1 to a payload vessel or the like for transportation back to Earth, to a recovery vessel, or to another destination. The sample containers in the payload vessel or recovery vessel may be stored in any suitable configuration, which may include vibration damping devices, and which may be in thermal communication (e.g., connected with copper braids and heat pipes) for thermal dissipation. The sample containers may be moved between the crystal growth furnace 1 and the payload vessel/recovery vessel using screws and cryogenic/high-vacuum grease, motors with encoders used to calculate relative movement, magnetic dampers to minimize vibrations reaching the crystal during recovery, and/or the like.

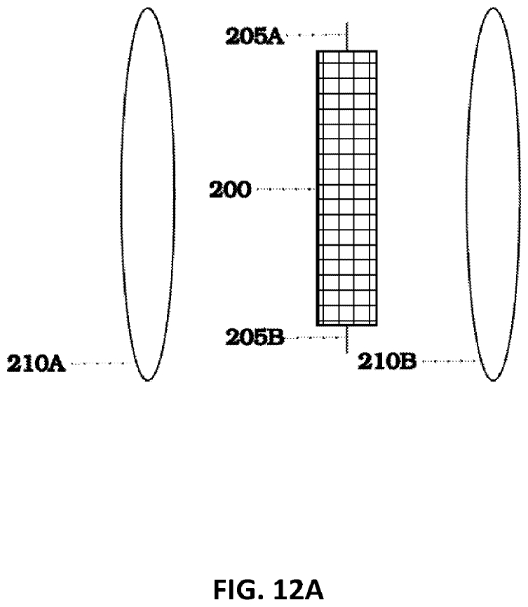

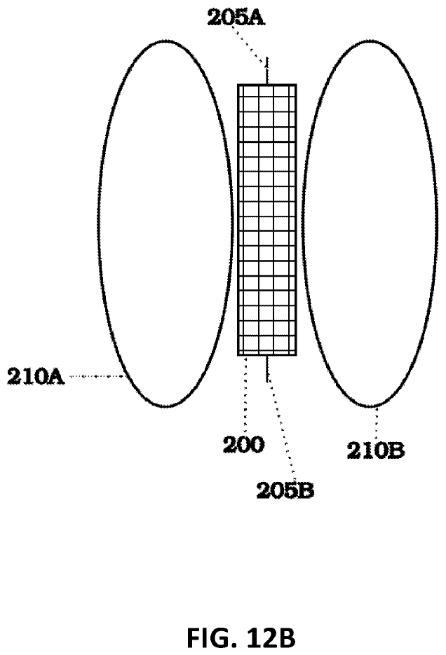

FIGS. 12A-12B illustrate embodiments of inflatable feedstock securing devices 210A, 210B dimensioned and configured for securing a crystal growth feedstock 200 within a crystal growth furnace (e.g., 1), with FIG. 12A illustrating the inflatable feedstock securing devices 210A, 210B being in a deflated configuration and FIG. 12B illustrating the inflatable feedstock securing devices 210A, 210B being in an inflated configuration. The inflatable feedstock securing devices 210A, 210B can be positioned about the crystal growth feedstock 200 between feedstock retention points 205A, 205B and can be configured to be inflated. The inflatable feedstock securing devices 210A, 210B can be in the deflated configuration to allow sufficient space in the crystallization portion or feedstock container 10 such that the crystal growth feedstock 200 can be disposed within the crystallization portion or feedstock container 10 within the crystal growth furnace 1. Then, after the crystal growth feedstock 200 is disposed within the crystallization portion or feedstock container 10 of the crystal growth furnace 1, the inflatable feedstock securing devices 210A, 210B can be inflated to transition the inflatable feedstock securing devices 210A, 210B from the first configuration to the second configuration such that an outer surface of the inflatable feedstock securing devices 210A, 210B is securely disposed against the outer surface of the crystal growth feedstock 200. Once the inflatable feedstock securing devices 210A, 210B are securely disposed against the outer surface of the crystal growth feedstock 200, the crystal growth furnace (e.g., 1) can be transported in a payload delivery vessel or otherwise moved without the acoustic and mechanical vibrations causing damage to the crystal growth feedstock 200.

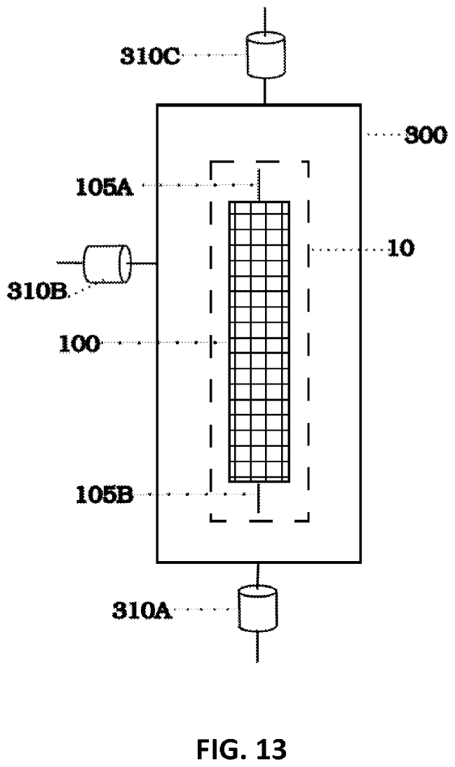

FIG. 13 illustrates a vibration damping device 300 dimensioned and configured for damping vibrations for a crystal growth furnace (e.g., 1) comprising the feedstock container 10 configured to retain the crystal growth feedstock 100 therein. In some embodiments, the vibration damping device 300 can be partially or fully disposed about a crystal growth furnace (e.g., 1). In some embodiments, the vibration damping device 300 can comprise a plurality of damper devices 310A, 310B, 310C. In some embodiments, the vibration damping device 300 can be configured such that the entire crystal growth furnace 1 is partially or mostly vibrationally isolated within a payload delivery vessel or transport vessel. In some embodiments, the plurality of damper devices 310A, 310B, 310C can be disposed at any suitable location about or within the crystal growth furnace 1. In some embodiments, the plurality of damper devices 310A, 310B, 310C can be positioned along a bottom surface, a top surface, a side surface, or within the crystal growth furnace 1. In some embodiments, the plurality of damper devices 310A, 310B, 310C can include any suitable number or type of damper device, such as those described elsewhere herein. While illustrated in FIG. 13 as including three damper devices, the vibration damping device 300 can include a single damper device, two damper devices, or more than three damper devices.

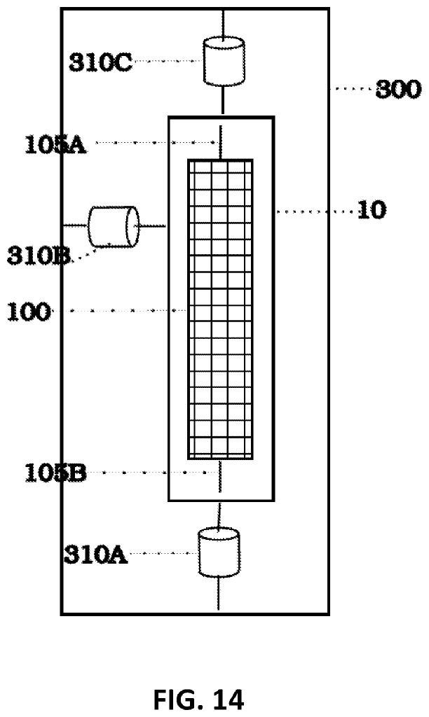

Additionally or alternatively, as illustrated in FIG. 14, an alternative embodiment of the vibration damping device 300 can include the vibration damping device 300 dimensioned and configured for damping vibrations for the feedstock container 10 configured to retain the crystal growth feedstock 100. In some embodiments, the vibration damping device 300 can be partially or fully disposed within a crystal growth furnace (e.g., 1). In some embodiments, the vibration damping device 300 can comprise a plurality of damper devices 310A, 310B, 310C. In some embodiments, the vibration damping device 300 can be configured such that the feedstock container 10 is partially or mostly vibrationally isolated within the crystal growth furnace (e.g., 1). In some embodiments, the plurality of damper devices 310A, 310B, 310C can be disposed at any suitable location about or within the feedstock container 10. In some embodiments, the plurality of damper devices 310A, 310B, 310C can be positioned along a bottom surface, a top surface, a side surface, or within the feedstock container 10. In some embodiments, the plurality of damper devices 310A, 310B, 310C can include any suitable number or type of damper device, such as those described elsewhere herein. While illustrated in FIG. 14 as including three damper devices, the vibration damping device 300 can include a single damper device, two damper devices, or more than three damper devices.

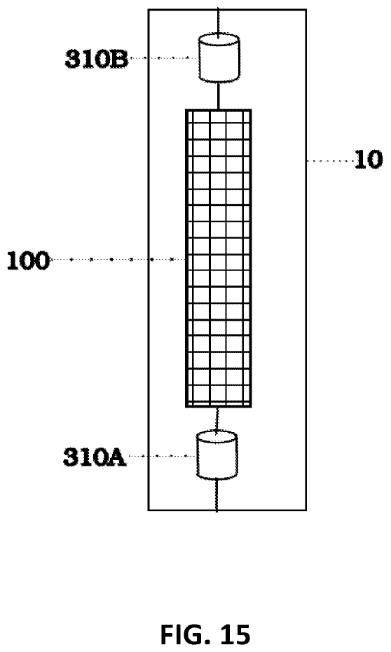

Additionally or alternative, as illustrated in FIG. 15, an embodiment of the feedstock container 10 can be configured and dimensioned for retaining the crystal growth feedstock 100 within the crystal growth furnace 1 in which the crystal growth feedstock 100 itself is vibrationally isolated from the rest of the sample container 10 using vibration damping devices 330A, 330B.

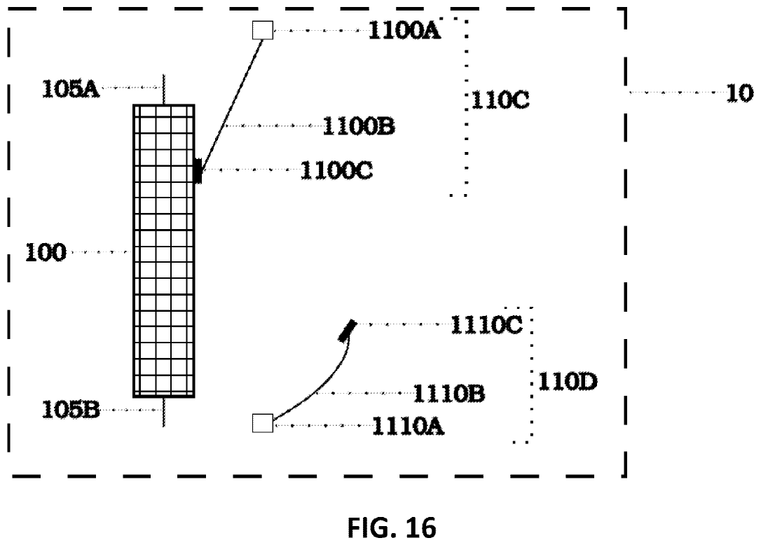

Additionally or alternatively, as illustrated in FIG. 16, an embodiment of the feedstock container 10 can include movable securing members 110C, 110D configured to retain the crystal growth feedstock 100 between the feedstock retention points 105A, 105B. In some embodiments, the movable securing members 110C, 110D can include pivot points 1100A, 1110A at a proximal ends of longitudinal portions 1100B, 1110B and contact members 1100C, 1110C at distal ends of the longitudinal portions 1100B, 1110B.

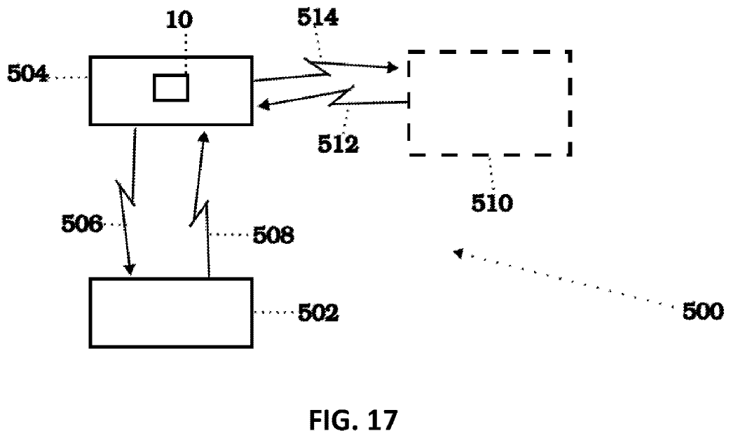

Referring now to FIG. 17, an approach 500 can be carried out as illustrated for controlling one or more operations of a crystal growth furnace (e.g., 1). The approach 500 can at least partially be initiated by, facilitated by, or carried out by a terrestrial remote-control device 502 configured to send commands 506 towards a crystal growth furnace 504 comprising a feedstock container 10. The commands 506 can comprise instructions related to the operation of the crystal growth furnace 504. The commands 506 can comprise instructions related to a position or movement or actuation of movable securing members (e.g., 110) and/or inflatable securing members (e.g., 210) within the crystal growth furnace 504, such as within the feedstock container 10.

The terrestrial remote-control device 502 can be further configured to receive feedback 508 from the crystal growth furnace 504, such as information related to a position or movement or actuation of movable securing members (e.g., 110) and/or inflatable securing members (e.g., 210) within the crystal growth furnace 504, such as within the feedstock container 10.

Additionally or alternatively, the approach 500 can at least partially be initiated by, facilitate by, or carried out by an extraterrestrial remote-control device 510 configured to send commands 512 towards the crystal growth furnace crystal growth furnace 504 comprising the feedstock container 10. The commands 512 can comprise instructions related to the operation of the crystal growth furnace 504. The commands 512 can comprise instructions related to a position or movement or actuation of movable securing members (e.g., 110) and/or inflatable securing members (e.g., 210) within the crystal growth furnace 504, such as within the feedstock container 10.

The extraterrestrial remote-control device 510 can be further configured to receive feedback 514 from the crystal growth furnace 504, such as information related to a position or movement or actuation of movable securing members (e.g., 110) and/or inflatable securing members (e.g., 210) within the crystal growth furnace 504, such as within the feedstock container 10.

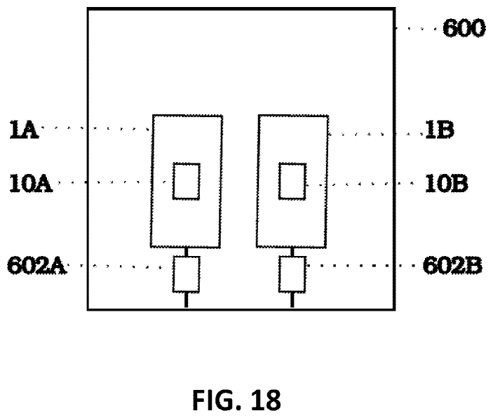

FIG. 18 illustrates an embodiment of an approach for a plurality of crystal growth furnaces 1A, 1B comprising, respectively, feedstock containers 10A, 10B, to be stored within a payload delivery vessel 600. The payload delivery vessel 600 can comprise damper devices 602A, 602B configured to at least partially isolate the crystal growth furnaces 1A, 1B from acoustic, mechanical, thermal, vibrational, or other perturbations that the crystal growth furnaces 1A, 1B would otherwise experience during transportation of the payload delivery vessel 600 to a reduced gravity environment, such as during a rocket launch, while incurring elevated gravity, and/or the like.

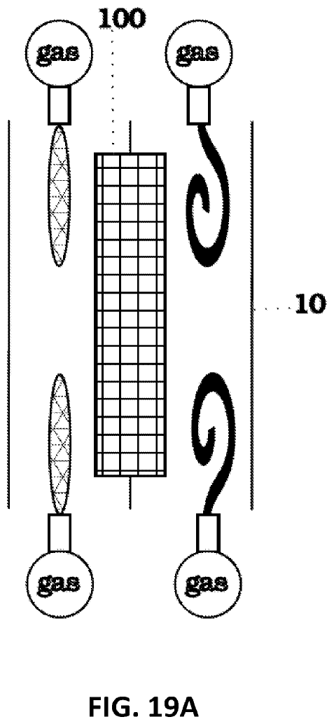

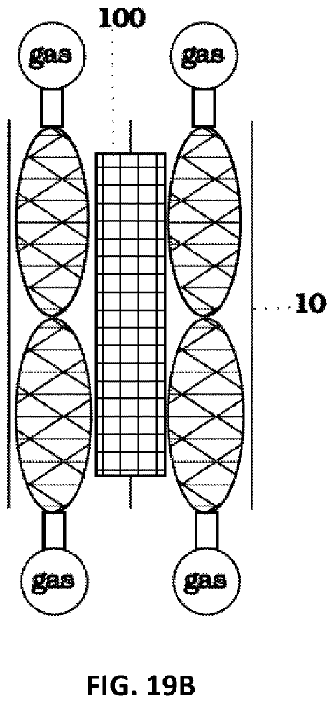

FIGS. 19A-19B illustrate an embodiment of the feedstock container 10 configured to secure therein the crystal growth feedstock 100 in which one or a plurality of inflatable feedstock securing devices (e.g., 210) are configured to be disposed between the crystal growth feedstock 100 and an inside of a rigid surface, such as an inner wall of the feedstock container 10.

In FIG. 19A, the inflatable feedstock securing devices are illustrating as being in a deflated configuration, while in FIG. 19B the inflatable feedstock securing devices in illustrated as being in an inflated configuration. The inflatable feedstock securing devices can be positioned about the crystal growth feedstock 100 between feedstock retention points (e.g., 105A, 105B) and can be configured to be inflated. The inflatable feedstock securing devices can be in the deflated configuration to allow sufficient space in the feedstock container 10 such that the crystal growth feedstock 100 can be disposed within the feedstock container 10 within the crystal growth furnace (e.g., 1). Then, after the crystal growth feedstock 100 is disposed within the feedstock container 10 of the crystal growth furnace, the inflatable feedstock securing devices can be inflated to transition the inflatable feedstock securing devices from the first configuration to the second configuration such that an outer surface of the inflatable feedstock securing devices are securely disposed against the outer surface of the crystal growth feedstock 100. Once the inflatable feedstock securing devices are securely disposed against the outer surface of the crystal growth feedstock 100, the crystal growth furnace (e.g., 1) can be transported in a payload delivery vessel or otherwise moved without the acoustic and mechanical vibrations causing damage to the crystal growth feedstock 100.

While the inflatable feedstock securing devices are illustrated in FIGS. 19A and 19B as being pneumatically inflatable, alternative embodiments are contemplated in which the inflatable feedstock securing devices are fluidically inflatable, mechanically inflatable, or otherwise able to be inflated to cushion the crystal growth feedstock 100 against vibrations and perturbations that would otherwise be incurred during transportation of the crystal growth furnace (e.g., 1). In some embodiments, the inflatable feedstock securing devices can be inflated with air, nitrogen gas, or another suitable gas. In other embodiments, the inflatable feedstock securing devices can be inflated with other fluids, such as liquids or supercritical fluids. For example, liquids and supercritical fluids are often incompressible, as compared to gases which are typically compressible. The incompressible or near incompressible nature of liquids and supercritical fluids or other viscous fluids may provide for additional support of the crystal growth feedstock and increased damping of different frequency vibrations.

While FIGS. 1-19B illustrate a variety of different securing mechanisms and devices, and a variety of different vibration damping mechanisms and devices, embodiments are contemplated in which more than one or all of the variety of different securing mechanisms and devices, and/or more than one or all of the variety of different vibration damping mechanisms and devices are implemented to reduce mechanical, vibrational, acoustic, thermal, or other damage to the crystal growth feedstock 100 before, during, and after transportation of the crystal growth furnace 1 to a reduced gravity environment, such as in a payload delivery vessel terrestrial launched into orbit about a planetary body or between planetary bodies and other space mass objects such as asteroids, manufacturing satellites, and/or the like.

### Computer Program Products, Methods, and Computing Entities

Embodiments of the present disclosure may be implemented in various ways, including as computer program products that comprise articles of manufacture. Such computer program products may include one or more software components including, for example, software objects, methods, data structures, or the like. A software component may be coded in any of a variety of programming languages. An illustrative programming language may be a lower-level programming language, such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD), solid state card (SSC), solid state module (SSM), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Low-Power Double Data Rate 4 (LPDDR4), LPDDR5, DDR4, DDR5 and/or other SDRAMs, Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), Compression Attached Memory Module (CAMM), CAMM2, Small Outline Dual In-line Memory Module (SO-DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As will be appreciated by a person skilled in the art, various embodiments of the present disclosure may also be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some embodiments, retrieval, loading, and/or execution may be performed in parallel such that multiple instructions are retrieved, loaded, and/or executed together. Thus, such embodiments can produce specifically-configured machines performing the steps or operations specified in the block diagrams and flowchart illustrations. Accordingly, the block diagrams and flowchart illustrations support various combinations of embodiments for performing the specified instructions, operations, or steps.

### Example Computing Entity

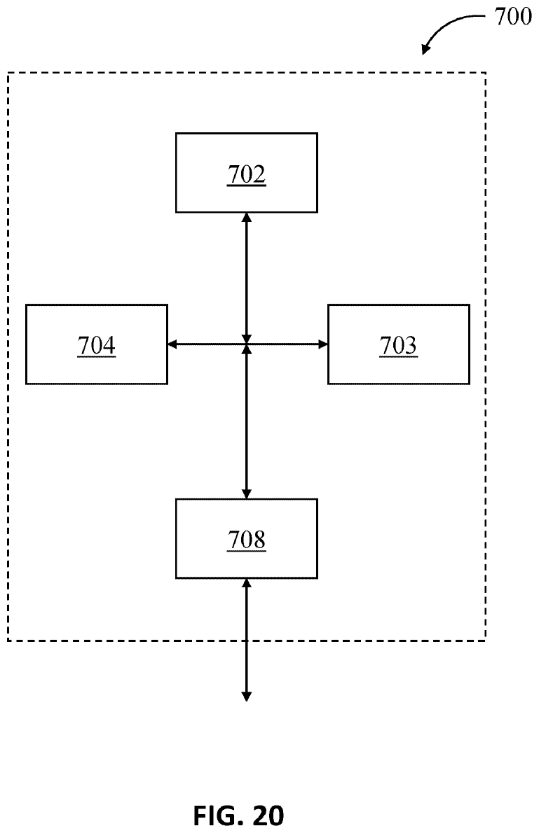

FIG. 20 provides a schematic of the computing device 700 according to one embodiment of the present disclosure. In general, the terms computing device, computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

As shown in FIG. 20, in one embodiment, the computing device 700 may include or be in communication with one or more processing elements 702 (also referred to as processors, processing circuitry, and/or similar terms used herein interchangeably) that communicate with other elements within the computing device 700 via a bus, for example. As will be understood, the processing element 702 may be embodied in a number of different ways. For example, the processing element 702 may be embodied as one or more complex programmable logic devices (CPLDs), microprocessors, multi-core processors, coprocessing entities, application-specific instruction-set processors (ASIPs), microcontrollers, and/or controllers. Further, the processing element 702 may be embodied as one or more other processing devices or circuitry. The term circuitry may refer to an entirely hardware embodiment or a combination of hardware and computer program products. Thus, the processing element 702 may be embodied as integrated circuits, application specific integrated circuits (ASICs), field programmable gate arrays (FPGAs), programmable logic arrays (PLAs), hardware accelerators, other circuitry, and/or the like. As will therefore be understood, the processing element 702 may be configured for a particular use or configured to execute instructions stored in volatile or non-volatile media or otherwise accessible to the processing element 702. As such, whether configured by hardware or computer program products, or by a combination thereof, the processing element 702 may be capable of performing steps or operations according to embodiments of the present disclosure when configured accordingly.

In some embodiments, the computing device 700 may further include or be in communication with non-volatile media (also referred to as non-volatile storage, memory, memory storage, memory circuitry, and/or similar terms used herein interchangeably). In one embodiment, the non-volatile storage or memory may include the one or more non-volatile memories 703, including but not limited to hard disks, ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. As will be recognized, the non-volatile storage or memory media may store databases, database instances, database management systems, data, applications, programs, program modules, scripts, source code, object code, byte code, compiled code, interpreted code, machine code, executable instructions, and/or the like. The term database, database instance, database management system, and/or similar terms used herein interchangeably may refer to a collection of records or data that is stored in a computer-readable storage medium using one or more database models, such as a hierarchical database model, network model, relational model, entity-relationship model, object model, document model, semantic model, graph model, and/or the like.

In some embodiments, the computing device 700 may further include or be in communication with volatile media (also referred to as volatile storage, memory, memory storage, memory circuitry, and/or similar terms used herein interchangeably). In one embodiment, the volatile storage or memory may also include one or more volatile memories 704, including but not limited to RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. As will be recognized, the volatile storage or memory media may be used to store at least portions of the databases, database instances, database management systems, data, applications, programs, program modules, scripts, source code, object code, byte code, compiled code, interpreted code, machine code, executable instructions, and/or the like being executed by, for example, the processing element 702. Thus, the databases, database instances, database management systems, data, applications, programs, program modules, scripts, source code, object code, byte code, compiled code, interpreted code, machine code, executable instructions, and/or the like may be used to control certain aspects of the operation of the computing device 700 with the assistance of the processing element 702 and operating system.

In some embodiments, the computing device 700 may also include one or more network interfaces, such as a network interface/transceiver 708 for communicating with various computing entities, such as by communicating data, content, information, and/or similar terms used herein interchangeably that can be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing device 700 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

Although not shown, the computing device 700 may include or be in communication with one or more input elements, such as a keyboard input, a mouse input, a touch screen/display input, motion input, movement input, audio input, pointing device input, joystick input, keypad input, and/or the like. The computing device 700 may also include or be in communication with one or more output elements (not shown), such as audio output, video output, screen/display output, motion output, movement output, and/or the like.

### Example External Computing Entity

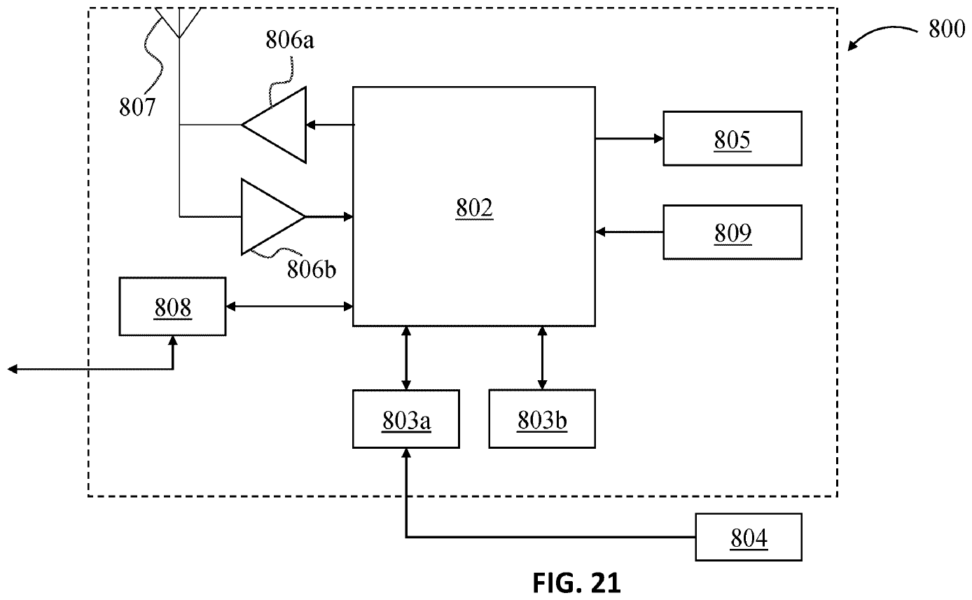

FIG. 21 provides an illustrative schematic representative of an external computing device 800 that can be used in conjunction with embodiments of the present disclosure. In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. The external computing device 90 can be operated by various parties. As shown in FIG. 21, the external computing device 800 can include an antenna 807, a transmitter 806a (e.g., radio), a receiver 806b (e.g., radio), and a processing element 802 (e.g., CPLDs, microprocessors, multi-core processors, coprocessing entities, ASIPs, microcontrollers, and/or controllers) that provides signals to and receives signals from the transmitter 806a and receiver 806b, correspondingly.

The signals provided to and received from the transmitter 806a and the receiver 806b, correspondingly, may include signaling information/data in accordance with air interface standards of applicable wireless systems. In this regard, the external computing device 800 may be capable of operating with one or more air interface standards, communication protocols, modulation types, and access types. More particularly, the external computing device 800 may operate in accordance with any of a number of wireless communication standards and protocols, such as those described above with regard to the computing device 700. In a particular embodiment, the external computing device 800 may operate in accordance with multiple wireless communication standards and protocols, such as UMTS, CDMA2000, 1×RTT, WCDMA, GSM, EDGE, TD-SCDMA, LTE, E-UTRAN, EVDO, HSPA, HSDPA, Wi-Fi, Wi-Fi Direct, WiMAX, UWB, IR, NFC, Bluetooth, USB, and/or the like. Similarly, the external computing device 800 may operate in accordance with multiple wired communication standards and protocols, such as those described above with regard to the computing device 700 via a network interface 808.

Via these communication standards and protocols, the external computing device 800 can communicate with various other entities using concepts, such as Unstructured Supplementary Service Data (USSD), Short Message Service (SMS), Multimedia Messaging Service (MMS), Dual-Tone Multi-Frequency Signaling (DTMF), and/or Subscriber Identity Module Dialer (SIM dialer). The external computing device 800 can also download changes, add-ons, and updates, for instance, to its firmware, software (e.g., including executable instructions, applications, program modules), and operating system.

According to one embodiment, the external computing device 800 may include location determining aspects, devices, modules, functionalities, and/or similar words used herein interchangeably. For example, the external computing device 800 may include outdoor positioning aspects, such as a location module adapted to acquire, for example, latitude, longitude, altitude, geocode, course, direction, heading, speed, universal time (UTC), date, and/or various other information/data. In one embodiment, the location module can acquire data, sometimes known as ephemeris data, by identifying the number of satellites in view and the relative positions of those satellites (e.g., using global positioning systems (GPS)). The satellites may be a variety of different satellites, including Low Earth Orbit (LEO) satellite systems, Department of Defense (DOD) satellite systems, the European Union Galileo positioning systems, the Chinese Compass navigation systems, Indian Regional Navigational satellite systems, and/or the like. This data can be collected using a variety of coordinate systems, such as the Decimal Degrees (DD); Degrees, Minutes, Seconds (DMS); Universal Transverse Mercator (UTM); Universal Polar Stereographic (UPS) coordinate systems; and/or the like. Alternatively, the location information/data can be determined by triangulating a position of the external computing device 800 in connection with a variety of other systems, including cellular towers, Wi-Fi access points, and/or the like. Similarly, the external computing device 800 may include indoor positioning aspects, such as a location module adapted to acquire, for example, latitude, longitude, altitude, geocode, course, direction, heading, speed, time, date, and/or various other information/data. Some of the indoor systems may use various position or location technologies, including RFID tags, indoor beacons or transmitters, Wi-Fi access points, cellular towers, nearby computing devices (e.g., smartphones, laptops), and/or the like. For instance, such technologies may include the iBeacons, Gimbal proximity beacons, Bluetooth Low Energy (BLE) transmitters, NFC transmitters, and/or the like. These indoor positioning aspects can be used in a variety of settings to determine the location of someone or something to within inches or centimeters.

The external computing device 800 may also comprise a user interface (that can include a display 805 coupled to the processing element 802) and/or a user input interface (coupled to the processing element 802). For example, the user interface may be a user application, browser, user interface, and/or similar words used herein interchangeably executing on and/or accessible via the external computing device 800 to interact with and/or cause display of information/data from the computing device 700, as described herein. The user input interface can comprise any of a number of devices or interfaces allowing the external computing device 800 to receive data, such as a keypad 809 (hard or soft), a touch display, voice/speech or motion interfaces, or other input device. In embodiments including the keypad 809, the keypad 809 can include (or cause display of) the conventional numeric (0-9) and related keys (#, *), and other keys used for operating the external computing device 800 and may include a full set of alphabetic keys or set of keys that may be activated to provide a full set of alphanumeric keys. In addition to providing input, the user input interface can be used, for example, to activate or deactivate certain functions, such as screen savers and/or sleep modes.

The external computing device 800 can also include volatile storage or memory 803a and/or non-volatile storage or memory 803b, which can be embedded and/or may be removable. For example, the non-volatile memory may be ROM, PROM, EPROM, EEPROM, flash memory, MMCs, SD memory cards, Memory Sticks, CBRAM, PRAM, FeRAM, NVRAM, MRAM, RRAM, SONOS, FJG RAM, Millipede memory, racetrack memory, and/or the like. The volatile memory may be RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory, register memory, and/or the like. The volatile and non-volatile storage or memory (803a, 803b) can store databases, database instances, database management systems, data, applications, programs, program modules, scripts, source code, object code, byte code, compiled code, interpreted code, machine code, executable instructions, and/or the like to implement the functions of the external computing device 800. As indicated, this may include a user application that is resident on the entity or accessible through a browser or other user interface for communicating with the computing device 700 and/or various other computing entities.

In another embodiment, the external computing device 800 may include one or more components or functionalities that are the same or similar to those of the computing device 700, as described in greater detail above. As will be recognized, these architectures and descriptions are provided for exemplary or illustrative purposes only and are not meant to limit the scope of this disclosure to one, some, or all of the various embodiments described herein.

In some embodiments, an apparatus/device for crystal growth and/or securing a crystal feedstock, such as shown, e.g., in FIGS. 1-19B, can comprise and/or be in communication with the computing device 700, the computing device 700 being suitable to carry out movement of the various components of the printing apparatus/device, flow rates or deposition/dispersal volumes, or the like. In some embodiments, the apparatus/device or a component thereof, e.g., the computing device 700, can be configured to be in communication with the external computing device 800, which can be configured to provide instructions for printing, a design file for a printed article, printing nozzle and/or non-solvent vapor dispersion apparatus path instructions, or the like to the computing device 700, which is configured to secure crystal growth feedstock and/or carry out crystal growth.

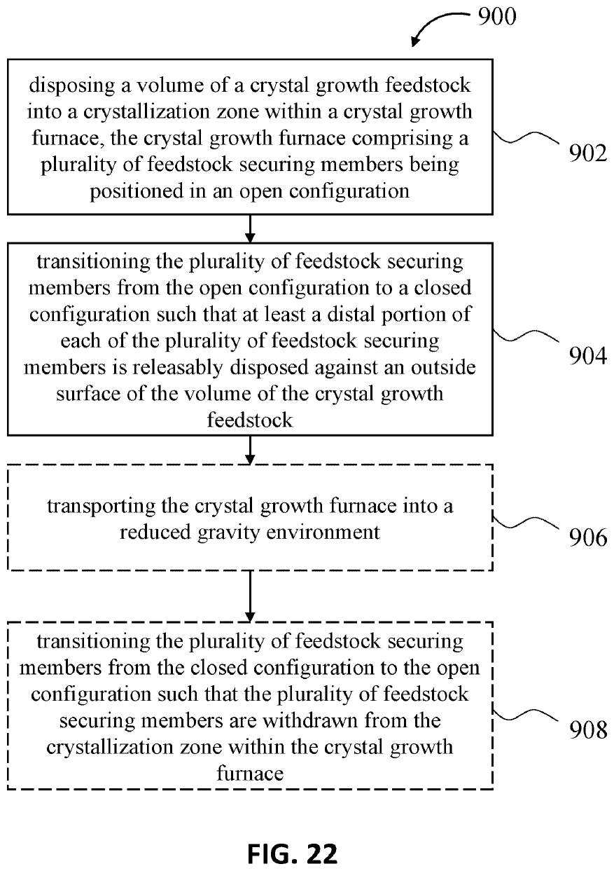

FIGS. 22-24 illustrate various methods, such as described elsewhere herein. The methods described herein can be carried out by means, such as the computing device 700 and/or the external computing device 800.

Referring now to FIG. 22, a method 900 is illustrated that comprises disposing a volume of a crystal growth feedstock into a crystallization zone with a crystal growth furnace, the crystal growth furnace comprising a plurality of feedstock securing members being positioned in an open configuration, at 902. The method 900 can further comprise transitioning the plurality of feedstock securing members from the open configuration to a closed configuration such that at least a distal portion of each of the plurality of feedstock securing members is securely disposed against an outside surface of the volume of the crystal growth feedstock, at 904. The method 900 can, optionally, further comprise transporting the crystal growth furnace into a reduced gravity environment, at 906. The method 900 can, optionally, further comprise transitioning the plurality of feedstock securing members from the closed configuration to the open configuration such that the plurality of feedstock securing members are withdrawn from the crystallization zone within the crystal growth furnace, at 908. Some or all elements/steps of the method 900 can be carried out by a device/apparatus, such as a crystal growth furnace or a component thereof. Some or all elements/steps of the method 900 can be carried out programmatically, such as by using a computing device (e.g., 700 and/or 800), which can be separate from or a part of a device/apparatus for crystal growth and/or securing crystal growth feedstock 100.

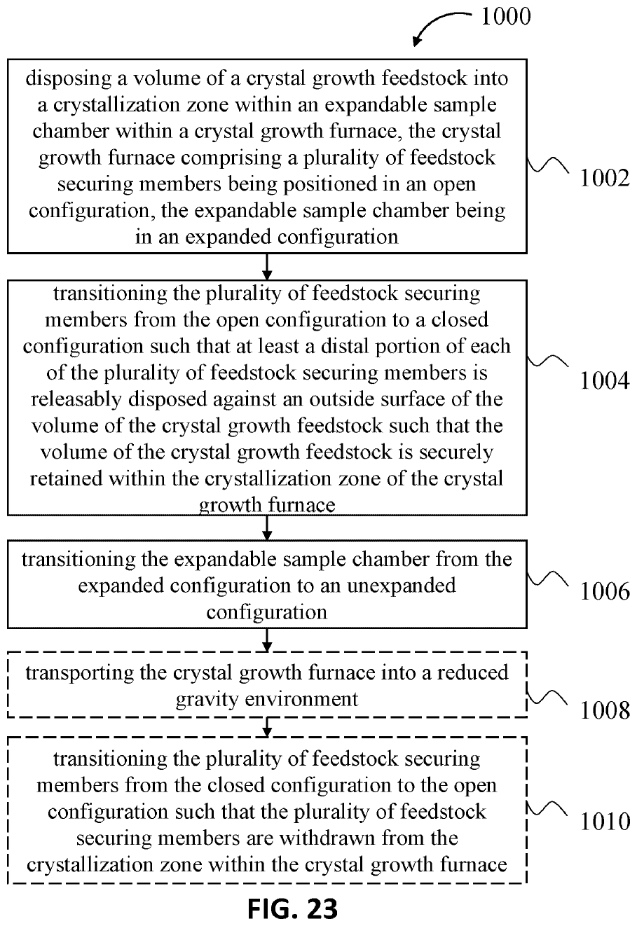

Referring now to FIG. 23, a method 1000 is illustrated that comprises transitioning the plurality of feedstock securing members from the closed configuration to the open configuration such that the plurality of feedstock securing members are withdrawn from the crystallization zone within the crystal growth furnace, at 1002. The method 1000 can further comprise transitioning the plurality of feedstock securing members from the closed configuration to the open configuration such that the plurality of feedstock securing members are withdrawn from the crystallization zone within the crystal growth furnace, at 1004. The method 1000 can further comprise transitioning the plurality of feedstock securing members from the closed configuration to the open configuration such that the plurality of feedstock securing members are withdrawn from the crystallization zone within the crystal growth furnace, at 1006. The method 1000 can, optionally, further comprise transporting the crystal growth furnace into a reduced gravity environment, at 1008. The method 1000 can, optionally, further comprise transitioning the plurality of feedstock securing members from the closed configuration to the open configuration such that the plurality of feedstock securing members are withdrawn from the crystallization zone within the crystal growth furnace, at 1010. Some or all elements/steps of the method 1000 can be carried out by a device/apparatus, such as a crystal growth furnace or a component thereof. Some or all elements/steps of the method 1000 can be carried out programmatically, such as by using a computing device (e.g., 700 and/or 800), which can be separate from or a part of a device/apparatus for crystal growth and/or securing crystal growth feedstock 100.

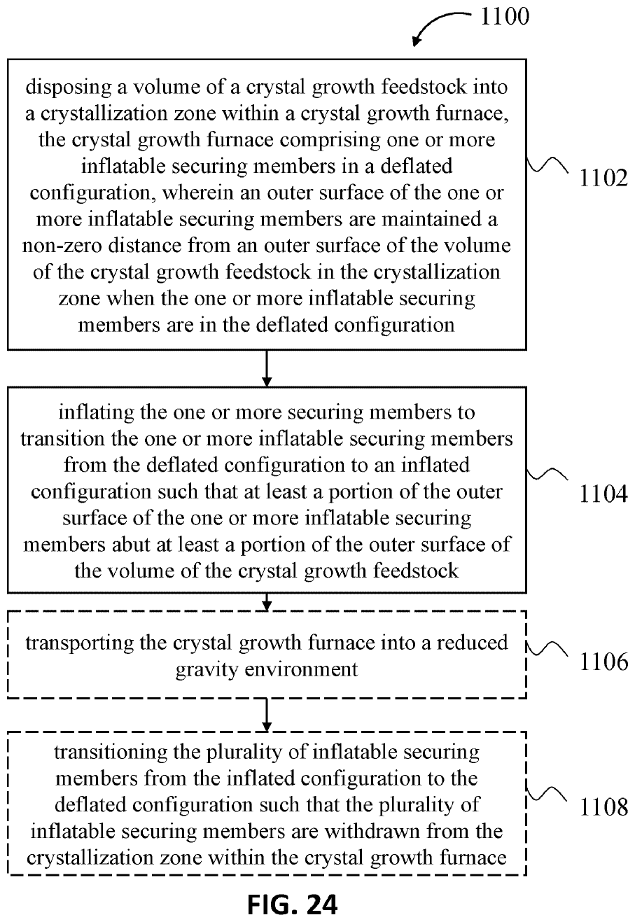

Referring now to FIG. 24, a method 1100 is illustrated that comprises disposing a volume of a crystal growth feedstock into a crystallization zone within a crystal growth furnace, the crystal growth furnace comprising one or more inflatable securing members in a deflated configuration, wherein an outer surface of the one or more inflatable securing members are maintained a non-zero distance from an outer surface of the volume of the crystal growth feedstock in the crystallization zone when the one or more inflatable securing members are in the deflated configuration, at 1102. The method 1100 can further comprise inflating the one or more inflatable securing members to transition the one or more inflatable securing members from the deflated configuration to an inflated configuration such that at least a portion of the outer surface of the one or more inflatable securing members abut at least a portion of the outer surface of the volume of the crystal growth feedstock, at 1104. The method 1100 can, optionally, further comprise transporting the crystal growth furnace into a reduced gravity environment, at 1106. The method 1100 can, optionally, further comprise transitioning the plurality of inflatable securing members from the inflated configuration to the deflated configuration such that the plurality of inflatable securing members are withdrawn from the crystallization zone within the crystal growth furnace, at 1108. Some or all elements/steps of the method 1100 can be carried out by a device/apparatus, such as a crystal growth furnace or a component thereof. Some or all elements/steps of the method 1100 can be carried out programmatically, such as by using a computing device (e.g., 700 and/or 800), which can be separate from or a part of a device/apparatus for crystal growth and/or securing crystal growth feedstock 100.

### CONCLUSIONS

Efforts have been made to ensure accuracy with respect to numbers used (e.g., amounts, temperature, etc.) but some experimental errors and deviations should be accounted for.

One skilled in the art will recognize many methods and materials similar or equivalent to those described herein, which could be used in the practicing the subject matter described herein. The present disclosure is in no way limited to just the methods and materials described.

Throughout this specification and the claims, the words “comprise,” “comprises,” and “comprising” are used in a non-exclusive sense, except where the context requires otherwise. It is understood that examples described herein include “consisting of” and/or “consisting essentially of” examples.

Where a range of values is provided, it is understood that each intervening value, to the tenth of the unit of the lower limit, unless the context clearly dictates otherwise, between the upper and lower limit of the range and any other stated or intervening value in that stated range, is encompassed. The upper and lower limits of these small ranges which may independently be included in the smaller rangers is also encompassed, subject to any specifically excluded limit in the stated range. Where the stated range includes one or both of the limits, ranges excluding either or both of those included limits are also included.

Many modifications and other examples set forth herein will come to mind to one skilled in the art to which this subject matter pertains having the benefit of the teachings presented in the foregoing descriptions and the associated drawings. Therefore, it is to be understood that the subject matter is not to be limited to the specific examples disclosed and that modifications and other examples are intended to be included within the scope of the appended claims. Although specific terms are employed herein, they are used in a generic and descriptive sense only and not for purposes of limitation.

It should be appreciated that all combinations of the foregoing concepts and additional concepts discussed in greater detail below (provided such concepts are not mutually inconsistent) are contemplated as being part of the inventive subject matter disclosed herein. In particular, the combinations of claimed subject matter appearing at the end of this disclosure are contemplated as being part of the inventive subject matter disclosed herein. It should be appreciated that terminology explicitly employed herein that also may appear in any disclosure incorporated by reference should be accorded a meaning consistent with the particular concepts disclosed herein.

In some embodiments, one or more of the operations, steps, elements, or processes described herein may be modified or further amplified as described below. Moreover, in some embodiments, additional optional operations may also be included. It should be appreciated that each of the modifications, optional additions, and/or amplifications described herein may be included with the operations previously described herein, either alone or in combination, with any others from among the features described herein.

The provided method description, illustrations, and process flow diagrams are provided merely as illustrative examples and are not intended to require or imply that the steps of the various embodiments must each or all be performed and/or should be performed in the order presented or described. As will be appreciated by one of skill in the art, the order of steps in some or all of the embodiments described may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an,” or “the” is not to be construed as limiting the element to the singular. Further, any reference to dispensing, disposing, depositing, dispersing, conveying, injecting, inserting, communicating, and other such terms of art are not to be construed as limiting the element to any particular means or method or apparatus or system, and is taken to mean conveying the material within the receiving vessel, solution, conduit, or the like by way of any suitable method.

Many modifications and other embodiments of the inventions set forth herein will come to mind to one skilled in the art to which these inventions pertain having the benefit of teachings presented in the foregoing descriptions and the associated drawings. Although the figures only show certain components of the apparatus and systems described herein, it is understood that various other components may be used in conjunction with the system. Therefore, it is to be understood that the inventions are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation. Specific equipment and materials described in the examples are for illustration only and not for purposes of limitation. For instance, any and all articles, portions of articles, structures, bulk materials, and/or the like, having any form factor, scale, dimensions, aesthetic attributes, material properties, internal structures, and/or mechanical properties, which are formed according to any of the disclosed methods, approaches, processes, or variations thereof, using any devices, equipment, apparatuses, systems, or variations thereof, using any of the build materials/resins described herein or variations thereof, are all contemplated and covered by the present disclosure. None of the examples provided are intended to, nor should they, limit in any way the scope of the present disclosure.

The various portions of the present disclosure, such as the Background, Summary, Brief Description of the Drawings, and Abstract sections, are provided to comply with requirements of the MPEP and are not to be considered an admission of prior art or a suggestion that any portion or part of the disclosure constitutes common general knowledge in any country in the world. The present disclosure is provided as a discussion of the inventor's own work and improvements based on the inventor's own work. See, e.g., Riverwood Int'l Corp. v. R. A. Jones & Co., 324 F.3d 1346, 1354 (Fed. Cir. 2003).

In some embodiments, one or more of the operations, steps, or processes described herein may be modified or further amplified as described below. Moreover, in some embodiments, additional optional operations may also be included. It should be appreciated that each of the modifications, optional additions, and/or amplifications described herein may be included with the operations previously described herein, either alone or in combination, with any others from among the features described herein.

Although specific advantages have been enumerated above, various embodiments may include some, none, or all of the enumerated advantages.

Other technical advantages may become readily apparent to one of ordinary skill in the art after review of the following figures and description.

It should be understood that, although exemplary embodiments are illustrated in the figures and described below, the principles of the present disclosure may be implemented using any number of techniques, whether currently known or not. The present disclosure should in no way be limited to the examples, experimental results, exemplary embodiments, preferred configurations, illustrated equipment, disclosed processes, or particular implementations and techniques illustrated in the drawings and described below.

The provided method description, illustrations, and process flow diagrams are provided merely as illustrative examples and are not intended to require or imply that the steps of the various embodiments must each or all be performed and/or should be performed in the order presented or described. As will be appreciated by one of skill in the art, the order of steps in some or all of the embodiments described may be performed in any order. Words such as “thereafter,” “then,” “next,” etc. are not intended to limit the order of the steps; these words are simply used to guide the reader through the description of the methods. Further, any reference to claim elements in the singular, for example, using the articles “a,” “an,” or “the” is not to be construed as limiting the element to the singular. Further, any reference to dispensing, disposing, depositing, dispersing, conveying, injecting, conveying, inserting, communicating, and other such terms of art are not to be construed as limiting the element to any particular means or method or apparatus or system, and is taken to mean conveying the material within the receiving vessel, solution, conduit, or the like by way of any suitable method.

Unless otherwise indicated, all numbers expressing quantities of equipment, number of steps, material quantities, material masses, material volumes, operating conditions, and so forth used in the specification and claims are to be understood as being modified in all instances by the term “about”. Accordingly, unless indicated to the contrary, the numerical parameters set forth in the present specification and attached claims are approximations that can vary depending upon the desired properties sought to be obtained by the present application. Generally, the term “about,” as used herein when referring to a measurable value such as an amount of weight, time, volume, ratio, temperature, etc., is meant to encompass ±50% of the stated value. For example, a value of “1,000,” which would be construed from above as meaning “about 1,000,” indicates a range of values from 500 to 1,500, inclusive of all values and ranges therebetween. As another example, a value of “about 1,000” should be taken to indicate any single value or sub-range of values from 500 to 1,500, inclusive of the values 500 and/or 1,500. As such, if a value of “about 1,000” is disclosed or claimed, this disclosure or claim element includes, for example, the value of 500, the value of 500.0000000000001, the value of 500.1, the value of 501, . . . the value of 1,000, . . . the value of 1,499.9999999, the value of 1,500, and all other values, ranges, or sub-ranges, therebetween, including values interstitial to adjacent integers or whole numbers, to any decimal place.

Generally, the term “substantially,” as used herein when referring to a measurable value, is meant to encompass ±50% of the stated value. Generally, the term “substantially,” as used herein with regard to a discrete position or orientation of a piece of equipment, component, or subcomponent, is meant to encompass the discrete position ±50% of the discrete position. Generally, the term “substantially,” as used herein with regard to a location of a piece of equipment, component, or subcomponent along a total range of travel of that equipment, component, or subcomponent, is meant to encompass ±50% of the location of the equipment, component, or subcomponent with regard to the total range of travel of that piece of equipment, component, or subcomponent, including translational travel, rotational travel, and extending travel in any direction, orientation, or configuration. As such, the use of the phrase “substantially disposed within a container” would be construed from above as meaning that greater than or equal to 50% of the subject element is disposed within the container.

All transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

Conventional terms in the fields of crystal growth, materials science, mechanical engineering, and inorganic chemistry have been used herein. The terms are known in the art and are provided only as a non-limiting example for convenience purposes. Accordingly, the interpretation of the corresponding terms in the claims, unless stated otherwise, is not limited to any particular definition. Thus, the terms used in the claims should be given their broadest reasonable interpretation.

Although the figures only show certain components of the apparatus and systems described herein, it is understood that various other components may be used in conjunction with the system. Therefore, it is to be understood that the inventions are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation. Specific equipment and materials described in the examples are for illustration only and not for purposes of limitation. For instance, any and all articles, portions of articles, structures, bulk materials, and/or the like, having any form factor, scale, dimensions, aesthetic attributes, material properties, internal structures, and/or mechanical properties, which are formed according to any of the disclosed methods, approaches, processes, or variations thereof, using any devices, equipment, apparatuses, systems, or variations thereof, using any of the build material, printing mixture, ink, yield-stress support material, or other material compositions described herein or variations thereof, are all contemplated and covered by the present disclosure. None of the examples provided are intended to, nor should they, limit in any way the scope of the present disclosure.

In this Detailed Description, various features may have been grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments may be combined with each other in various combinations or permutations. The scope of the embodiments should be determined with reference to the appended claims, along with the full scope of equivalents to which such claims are entitled.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that some or all of the parameters, dimensions, materials, equipment, processes, methods, and configurations described herein are meant to be preferred examples and that the actual parameters, dimensions, materials, and/or configurations will depend upon the specific application or applications for which the inventive teachings are used. Those skilled in the art will recognize many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” Any ranges cited herein are inclusive.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein “at. %” refers to atomic percent, “vol. %” refers to volume percent, and “wt. %” refers to weight percent. However, in certain embodiments when “at. %” is utilized, the values described may also describe “vol. %” and/or “wt. %,” when “vol. %” is utilized, the values described may also describe “at. %” and/or “wt. %,” and when “wt. %” is utilized, the values described may also describe “at. %” and/or “vol. %.” For example, if “20 at. %” is described in one embodiment, in other embodiments the same description may refer to “20 wt. %” or “20 vol. %.” As a result, all “at. %” values should be understood to also refer to “wt. %” in some instances and “vol. %” in other instances, all “vol. %” values should be understood to also refer to “wt. %” values in some instances and “at. %” in other instances, and all “wt. %” values should be understood to refer to “at. %”in some instances and “vol. %”in other instances.

The claims should not be read as limited to the described order or elements unless stated to that effect. It should be understood that various changes in form and detail may be made by one of ordinary skill in the art without departing from the spirit and scope of the appended claims. All embodiments that come within the spirit and scope of the following claims and equivalents thereto are claimed.

1. A device configured to secure crystal growth feedstock in a crystal growth furnace, the device comprising:
a crystallization zone configured to retain a volume of crystal growth feedstock; and
a plurality of movable securing members, respective movable securing members of the plurality of movable securing members comprising a distal portion configured to be disposed against an outside surface of the volume of the crystal growth feedstock when the plurality of movable securing members are in a first configuration and configured to be positioned a non-zero distance from the outside surface of the volume of the crystal growth feedstock when the plurality of movable securing members are in a second configuration.

2. A device configured to secure crystal growth feedstock in a crystal growth furnace, the device comprising:
an expandible sample chamber comprising a flexible enclosure material, wherein when the expandible sample chamber is in a first configuration the expandible sample chamber is expanded to a maximum internal volume, and wherein when the expandible sample chamber is in a second configuration the expandible sample chamber is collapsed to a minimum internal volume;
a crystallization zone configured to retain a volume of crystal growth feedstock; and
a plurality of movable securing members, respective movable securing members of the plurality of movable securing members comprising a distal portion configured to be disposed against an outside surface of the volume of the crystal growth feedstock when the plurality of movable securing members are in a secured configuration and configured to be positioned a non-zero distance from the outside surface of the volume of the crystal growth feedstock when the plurality of movable securing members are in an extended configuration.

3. A device configured to secure crystal growth feedstock in a crystal growth furnace, the device comprising:
a crystallization zone configured to retain a volume of crystal growth feedstock; and
one or more inflatable securing members,
wherein the one or more inflatable securing members are configured, when in a deflated configuration, such that an outer surface of the one or more inflatable securing members are maintained a non-zero distance from an outer surface of the volume of the crystal growth feedstock in the crystallization zone, and
wherein the one or more inflatable securing members are configured, when in an inflated configuration, to be inflated such that at least a portion of the outer surface of the one or more inflatable securing members abut at least a portion of the outer surface of the volume of the crystal growth feedstock.

4. A device configured to secure crystal growth feedstock in a crystal growth furnace, the device comprising:
an expandible sample chamber comprising a flexible enclosure material and defining a collapsed volume within the flexible enclosure material;
a plurality of feedstock retention points within the expandible sample chamber, the plurality of feedstock retention points defining a crystal growth region;
one or more seed crystals disposed within the expandible sample chamber, at least one of the seed crystals being located at a feedstock retention point;
a thermocouple configured to communicate heat to one or more portions of the crystal growth region within the expandable sample chamber; and
a plurality of movable securing members configured to retain a volume of a solid or semi-solid feedstock within the crystal growth region of the expandible sample chamber.

5. The device of claim 4, wherein the expandible sample chamber is configured to be expanded from the collapsed volume to an expanded volume greater than the collapsed volume.

6. The device of claim 5, wherein the expandible sample chamber is configured to be expanded from the collapsed volume to the expanded volume by communicating one or more gases into the collapsed volume within the flexible enclosure material.

7. The device of claim 5, wherein the plurality of movable securing members are configured to be moved from a feedstock retaining configuration to a feedstock released configuration once the expandible sample chamber is expanded from the collapsed volume to the expanded volume.

8. A crystal growth furnace comprising:
an expandible sample container configured to be heated to between about 200° C. and about 6,000° C. to facilitate crystal growth from a volume of a crystal growth feedstock, wherein the expandible sample container is configured to be in a contracted configuration before and during transportation of the crystal growth furnace into a zero-gravity environment, the expandible sample container being further configured to transition from the contracted configuration to an expanded configuration once the crystal growth furnace is in the zero gravity environment and before the crystal growth;
a crystal growth feedstock chamber positioned within the expandible sample container and configured to receive the volume of the crystal growth feedstock; and
a plurality of feedstock securing members configured to secure the volume of the crystal growth feedstock within the crystal growth feedstock chamber when positioned in a securing configuration during transportation of the crystal growth furnace into the zero gravity environment, the plurality of feedstock securing members being further configured to transition from the securing configuration to a released configuration once the crystal growth furnace is in the zero gravity environment and before crystal growth.

9. The crystal growth furnace of claim 8, further comprising:
a thermocouple configured to communicate heat to at least a portion of the volume of the feedstock within the crystal growth feedstock chamber.

10. The crystal growth furnace of claim 8, wherein the expandible sample container is configured to be expanded from the contracted configuration to the expanded configuration by communicating one or more gases into the expandible sample container of the crystal growth furnace.

11. The crystal growth furnace of claim 8, wherein, when the plurality of feedstock securing members are in the securing configuration, at least a portion of respective feedstock securing members of the plurality of feedstock securing members are in contact with an outside surface of the volume of the crystal growth feedstock in the crystal growth feedstock chamber within the expandible sample container.

12. The crystal growth furnace of claim 11, wherein, when the plurality of feedstock securing members are in the released configuration, at least a portion of respective feedstock securing members of the plurality of feedstock securing members are maintained a non-zero distance from the outside surface of the volume of the crystal growth feedstock in the crystal growth feedstock chamber within the expandible sample container.

13. A method comprising:
disposing a volume of a crystal growth feedstock into a crystallization zone within a crystal growth furnace, the crystal growth furnace comprising a plurality of feedstock securing members being positioned in an open configuration; and
transitioning the plurality of feedstock securing members from the open configuration to a closed configuration such that at least a distal portion of each of the plurality of feedstock securing members is releasably disposed against an outside surface of the volume of the crystal growth feedstock such that the volume of the crystal growth feedstock is securely retained within the crystallization zone of the crystal growth furnace.

14. The method of claim 13, further comprising:
transporting the crystal growth furnace into a reduced gravity environment; and
transitioning the plurality of feedstock securing members from the closed configuration to the open configuration such that the plurality of feedstock securing members are withdrawn from the crystallization zone within the crystal growth furnace.

15. A method comprising:
disposing a volume of a crystal growth feedstock into a crystallization zone within an expandable sample chamber within a crystal growth furnace, the crystal growth furnace comprising a plurality of feedstock securing members being positioned in an open configuration, the expandable sample chamber being in an expanded configuration;
transitioning the plurality of feedstock securing members from the open configuration to a closed configuration such that at least a distal portion of each of the plurality of feedstock securing members is releasably disposed against an outside surface of the volume of the crystal growth feedstock such that the volume of the crystal growth feedstock is securely retained within the crystallization zone of the crystal growth furnace; and
transitioning the expandable sample chamber from the expanded configuration to an unexpanded configuration.

16. The method of claim 15, further comprising:
transporting the crystal growth furnace into a reduced gravity environment; and
transitioning the plurality of feedstock securing members from the closed configuration to the open configuration such that the plurality of feedstock securing members are withdrawn from the crystallization zone within the crystal growth furnace.

17. A method comprising:
disposing a volume of a crystal growth feedstock into a crystallization zone within a crystal growth furnace, the crystal growth furnace comprising one or more inflatable securing members in a deflated configuration, wherein an outer surface of the one or more inflatable securing members are maintained a non-zero distance from an outer surface of the volume of the crystal growth feedstock in the crystallization zone when the one or more inflatable securing members are in the deflated configuration; and
inflating the one or more inflatable securing members to transition the one or more inflatable securing members from the deflated configuration to an inflated configuration such that at least a portion of the outer surface of the one or more inflatable securing members abut at least a portion of the outer surface of the volume of the crystal growth feedstock.

18. The method of claim 17, further comprising:
transporting the crystal growth furnace into a reduced gravity environment; and
transitioning the plurality of inflatable securing members from the inflated configuration to the deflated configuration such that the plurality of inflatable securing members are withdrawn from the crystallization zone within the crystal growth furnace.

19. A method comprising:
communicating a volume of a crystal growth feedstock into a crystallization zone within an expandible sample container of a crystal growth furnace while the expandible sample container is in an expanded configuration;
transitioning a plurality of feedstock securing members from a released configuration, in which a distal portion of each of the plurality of feedstock securing members are maintained a non-zero distance above an outside surface of the volume of the crystal growth feedstock, to a securing configuration, in which a distal portion of each of the plurality of feedstock securing members are maintained in securing contact with the outside surface of the volume of the crystal growth feedstock such that the volume of the crystal growth feedstock is retained within the crystallization zone within the expandible sample container of the crystal growth furnace during transportation of the crystal growth furnace into a zero-gravity environment; and
transitioning the expandible sample container from the expanded configuration to a collapsed configuration before transportation of the crystal growth furnace into the zero-gravity environment.

20. The method of claim 19, wherein the crystallization zone comprises a traveling solvent floating zone.

21. The method of claim 19, wherein the crystal growth feedstock comprises a polycrystalline material.

22. A method comprising:
providing a crystal growth furnace comprising an expandible sample container in a collapsed configuration, the crystal growth furnace comprising a crystallization zone, and a volume of a crystal growth feedstock positioned within the crystallization zone, the crystal growth furnace further comprising a plurality of feedstock securing members positioned about the crystal growth feedstock in an inner volume of the expandible sample container and configured, in a securing configuration in which a distal portion of respective of the plurality of feedstock securing members are in securing contact with an outside surface of the volume of the crystal growth feedstock, to retain the volume of the crystal growth feedstock within the crystallization zone of the crystal growth furnace before and during transportation of the crystal growth furnace into a zero-gravity environment;
transitioning the expandible sample container from the collapsed configuration to an expanded configuration;
transitioning the plurality of feedstock securing members from the securing configuration to a released configuration in which the distal portion of respective of the plurality of feedstock securing members are maintained a non-zero distance above the outside surface of the volume of the crystal growth feedstock;
heating at least a portion of the crystallization zone to form a hot zone within the volume of the crystal growth feedstock;
while maintaining a temperature in the hot zone within a predetermined temperature range, allowing deposition of the crystal growth feedstock onto one or more seed crystals positioned within the crystallization zone of the crystal growth feedstock; and
allowing the crystallization zone to cool to a temperature below the predetermined temperature range to allow for formation of a monocrystalline structure from the crystal growth feedstock.
